(19) United States
(12) Patent Application Publication
(10) Pub. No.: US 2013/0207102 A1
(43) Pub. Date: Aug. 15, 2013

(54) SEMICONDUCTOR DEVICE

(71) Applicant: Semiconductor Energy Laboratory Co., Ltd., (US)

(72) Inventors: Hiroyuki MIYAKE, Atsugi (JP); Makoto KANEYASU, Hadano (JP)

(73) Assignee: SEMICONDUCTOR ENERGY LABORATORY CO., LTD., Atsugi-shi (JP)

(21) Appl. No.: 13/761,399

(22) Filed: Feb. 7, 2013

(30) Foreign Application Priority Data
Feb. 15, 2012 (JP) 2012-030720

(51) Int. Cl. H01L 29/786

(52) U.S. Cl. CPC H01L 29/7869
USPC 257/43

(57) ABSTRACT

A transistor using an oxide semiconductor film is provided, the transistor having a small parasitic capacitance and including a back-gate electrode with a high controllability of threshold voltage. In the transistor using an oxide semiconductor film, the back-gate electrode overlaps with a drain electrode and does not overlap with a source electrode. By providing the back-gate electrode so as to overlap with the drain electrode and not to overlap with the source electrode, the operation speed of the transistor can be increased without decreasing the controllability of threshold voltage of the transistor as compared with the case where the back-gate electrode is provided so as to overlap with both the drain electrode and the source electrode.

### BACKGROUND OF THE INVENTION

1. Field of the Invention

The present invention relates to a semiconductor device and a manufacturing method thereof.

Note that in this specification, a semiconductor device refers to any device that can function by utilizing semiconductor characteristics, and an electro-optical device, a semiconductor circuit, an electronic device, and the like are all included in the category of the semiconductor device.

2. Description of the Related Art

Attention has been focused on a technique for forming a transistor using a semiconductor film which is formed on a substrate having an insulating surface. The transistor has been widely used for semiconductor devices such as integrated circuits (ICs) and image display devices (display devices). A silicon film is known as a semiconductor film applicable to a transistor. As another semiconductor film, an oxide semiconductor film has been attracting attention recently.

For example, a transistor using the following amorphous oxide semiconductor film is disclosed: the amorphous oxide semiconductor film contains indium, gallium, and zinc and has an electron carrier concentration of lower than 10¹⁸/cm³ (see Patent Document 1).

Since an oxide semiconductor film has a higher carrier mobility than an amorphous silicon film, the operation speed of a transistor using the oxide semiconductor film is significantly higher than that of a transistor using the amorphous silicon film. There is also an advantage that capital investment can be reduced because part of production equipment for a transistor using an amorphous silicon film can be retrofitted and utilized.

Unlike the threshold voltage of a transistor using a silicon film, the threshold voltage of a transistor using an oxide semiconductor film cannot be easily controlled by impurity implantation or the like. Therefore, it has been proposed to control the threshold voltage with use of a back-gate electrode.

When a transistor includes a back-gate electrode, the threshold voltage thereof can be controlled; however, in some cases, the parasitic capacitance thereof increases and the operation speed thereof is decreased as compared to a transistor without a back-gate electrode. Hence, a technique has been proposed for reducing the area of a back-gate electrode so as to decrease the parasitic capacitance (see Patent Documents 2 and 3).

### REFERENCES

### Patent Documents

[Patent Document 1] Japanese Published Patent Application No. 2006-165528
[Patent Document 2] Japanese Published Patent Application No. 2010-123938
[Patent Document 3] Japanese Published Patent Application No. 2010-123939

### SUMMARY OF THE INVENTION

However, in a transistor using an oxide semiconductor film which includes a back-gate electrode, when the area of the back-gate electrode is reduced to decrease the parasitic capacitance, the controllability of threshold voltage is also reduced in some cases.

Thus, an object of one embodiment of the present invention is to provide, for example, a transistor using an oxide semiconductor film, which has a small parasitic capacitance and includes a back-gate electrode with a high controllability of threshold voltage.

Another object of one embodiment of the present invention is to provide, for example, a semiconductor device using such a transistor.

One embodiment of the present invention is, for example, a transistor using an oxide semiconductor film, in which a back-gate electrode is provided so as to overlap with a drain electrode and not to overlap with a source electrode.

Here, a transistor including a back-gate electrode is, for example, a transistor including gate electrodes with a channel region interposed therebetween. The back-gate electrode is, for example, a gate electrode in contact with a gate insulating film having a larger equivalent oxide thickness.

The inventors have found that, by providing the back-gate electrode so as to overlap with the drain electrode and not to overlap with the source electrode, the operation speed of the transistor can be increased without decreasing the controllability of threshold voltage of the transistor as compared with the case where the back-gate electrode is provided so as to overlap with both the drain electrode and the source electrode.

An electric field of a drain electrode causes a depletion layer in a transistor to expand in a channel region in the vicinity of an edge of the drain electrode. As a result, for example, a phenomenon called drain induced barrier lowering (DIBL) occurs, which may cause an increase in the off-state current of the transistor and a change in threshold voltage. A back-gate electrode overlapping with the vicinity of the edge of the drain electrode in the channel region makes it possible to suppress the expansion of the depletion layer, and thus to suppress an increase in off-state current and to increase the controllability of threshold voltage.

Hence, an increase in off-state current can be suppressed and a high controllability of threshold voltage can be achieved when the back-gate electrode overlaps not with the vicinity of the edge of the source electrode but with the vicinity of the edge of the drain electrode in the channel region.

According to one embodiment of the present invention, since a back-gate electrode does not overlap with a source electrode, an increase in parasitic capacitance can be reduced without reducing the controllability of threshold voltage with the back-gate electrode. Furthermore, an increase in the off-state current of a transistor can be suppressed.

One embodiment of the present invention is, for example, a semiconductor device including a first gate electrode over a substrate having an insulating surface, a first gate insulating film over the first gate electrode, an oxide semiconductor film which is over the first gate insulating film and overlaps with the first gate electrode, a source electrode and a drain electrode in contact with the oxide semiconductor film, a second gate insulating film over the oxide semiconductor film, the source electrode, and the drain electrode, and a second gate electrode over the second gate insulating film. The oxide semiconductor film includes a channel region between the source electrode and the drain electrode, and the second gate electrode overlaps with the channel region and the drain electrode and does not overlap with the source electrode.

In the semiconductor device, for example, the second gate insulating film has an equivalent oxide thickness larger than that of the first gate insulating film.

In the semiconductor device, for example, an area where the second gate electrode overlaps with the drain electrode has a width of 1 μm to 3 μm.

In the semiconductor device, for example, the second gate electrode overlaps with the center of the channel region.

Another embodiment of the present invention is, for example, a semiconductor device including a first gate electrode over a substrate having an insulating surface, a first gate insulating film over the first gate electrode, an oxide semiconductor film which is over the first gate insulating film and overlaps with the first gate electrode, a source electrode and a drain electrode in contact with the oxide semiconductor film, a second gate insulating film over the oxide semiconductor film, the source electrode, and the drain electrode, and a second gate electrode over the second gate insulating film. The oxide semiconductor film includes a channel region between the source electrode and the drain electrode, and the first gate electrode overlaps with the channel region and the drain electrode and does not overlap with the source electrode.

In the semiconductor device, for example, the first gate insulating film has an equivalent oxide thickness larger than that of the second gate insulating film.

In the semiconductor device, for example, an area where the first gate electrode overlaps with the drain electrode has a width of 1 μm to 3 μm.

In the semiconductor device, for example, the first gate electrode overlaps with the center of the channel region.

Note that the aforementioned embodiments of the present invention are examples. For example, the semiconductor film is not limited to the oxide semiconductor film in some cases. For example, a silicon layer, an organic semiconductor layer, and other compound semiconductor layers (such as gallium arsenide, silicon carbide, or gallium nitride) may be used instead of the oxide semiconductor film.

It is possible to provide a transistor using an oxide semiconductor film, which has a high controllability of threshold voltage and a high operation speed. Alternatively, it is possible to provide a transistor with a high controllability of threshold voltage, or a transistor with a high operation speed. It is also possible to provide a transistor with stable electrical characteristics. Further, it is possible to provide a transistor with a low off-state current.

Furthermore, a semiconductor device using the transistor can be provided.

### BRIEF DESCRIPTION OF THE DRAWINGS

In the accompanying drawings:

FIG. 1A is a top view illustrating an example of a transistor of one embodiment of the present invention, and FIGS. 1B and 1C are cross-sectional views thereof;

FIG. 2A is a top view illustrating an example of a transistor of one embodiment of the present invention, and FIGS. 2B and 2C are cross-sectional views thereof;

FIG. 3A is a top view illustrating an example of a transistor of one embodiment of the present invention, and FIGS. 3B and 3C are cross-sectional views thereof;

FIG. 4A is a top view illustrating an example of a transistor of one embodiment of the present invention, and FIGS. 4B and 4C are cross-sectional views thereof;

FIGS. 5A to 5C are cross-sectional views illustrating an example of a method for manufacturing a transistor of one embodiment of the present invention;

FIGS. 6A to 6C are cross-sectional views illustrating an example of the method for manufacturing the transistor of one embodiment of the present invention;

FIG. 7A is a circuit diagram illustrating an example of an EL display device of one embodiment of the present invention, and FIGS. 7B and 7C are cross-sectional views thereof;

FIGS. 8A to 8D are circuit diagrams illustrating examples of an inverter of one embodiment of the present invention;

FIG. 9 is a circuit diagram illustrating an example of a semiconductor device of one embodiment of the present invention;

FIG. 10 is a block diagram illustrating a specific example of a CPU of one embodiment of the present invention;

FIGS. 11A to 11D are perspective views illustrating examples of an electronic device of one embodiment of the present invention;

FIGS. 12A to 12C are cross-sectional views of transistors; and

FIG. 13 is a circuit diagram of a ring oscillator.

### DETAILED DESCRIPTION OF THE INVENTION

Embodiments of the present invention will be described in detail with reference to the accompanying drawings. Note that the present invention is not limited to the description below, and it is easily understood by those skilled in the art that modes and details can be modified in various ways. Therefore, the present invention is not construed as being limited to description of the embodiments. In the description of the structures of the present invention with reference to the drawings, the same reference numerals are used in common for the same portions in different drawings. Note that the same hatch pattern is applied to similar parts, and the similar parts are not especially denoted by reference numerals in some cases.

A voltage usually refers to a potential difference between a given potential and a reference potential (e.g., a source potential or a ground potential (GND)). A voltage can be referred to as a potential and vice versa.

Even when the expression “electrically connect” is used in this specification, in an actual circuit, there is a case in which no physical connection is made and a wiring is just extended.

Note that the ordinal numbers such as “first” and “second” in this specification are used for convenience and do not denote the order of steps or the stacking order of layers. In addition, the ordinal numbers in this specification do not denote particular names which specify the present invention.

### Embodiment 1

In this embodiment, a transistor of one embodiment of the present invention will be described.

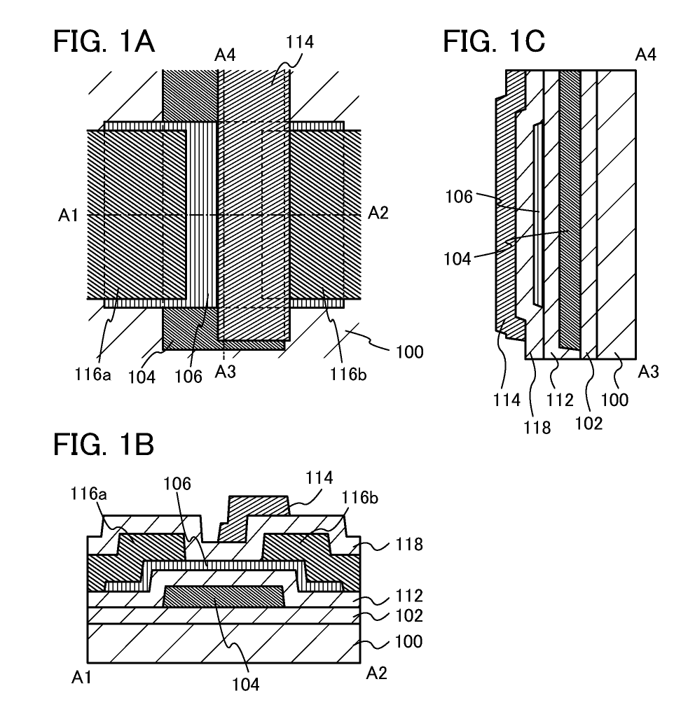

FIG. 1A is a top view of a transistor of one embodiment of the present invention. FIG. 1B is a cross-sectional view along dashed-dotted line A1-A2 of FIG. 1A. FIG. 1C is a cross-sectional view along dashed-dotted line A3-A4 of FIG. 1A. Note that a base insulating film 102 and the like are not illustrated in FIG. 1A for simplicity.

FIG. 1B is a cross-sectional view of a transistor including a base insulating film 102 over a substrate 100, a gate electrode 104 over the base insulating film 102, a gate insulating film 112 over the gate electrode 104, an oxide semiconductor film 106 which is over the gate insulating film 112 and overlaps with the gate electrode 104, a source electrode 116a and a drain electrode 116b which are over the oxide semiconductor film 106, a gate insulating film 118 over the oxide semiconductor film 106, the source electrode 116a, and the drain electrode 116b, and a gate electrode 114 which is over the gate insulating film 118, overlaps with the oxide semiconductor film 106 and the drain electrode 116b, and does not overlap with the source electrode 116a.

Note that in the oxide semiconductor film 106, a region overlapping with the gate electrode 104 and interposed between the source electrode 116a and the drain electrode 116b is a channel region. Thus, the center of the channel region is at the same distance from the source electrode 116a and the drain electrode 116b. Accordingly, in FIGS. 1A to 1C, dashed-dotted line A3-A4 passes through the center of the channel region.

Here, the gate electrode 104 overlaps with the source electrode 116a and the drain electrode 116b. Further, the gate electrode 114 overlaps with the center of the channel region. Moreover, a region where the gate electrode 114 overlaps with the drain electrode 116b has a width of 1 μm to 3 μm in a channel length direction.

The gate insulating film 118 has an equivalent oxide thickness larger than that of the gate insulating film 112. Note that the equivalent oxide thickness is obtained by converting the physical thickness of a film to the electrical thickness equivalent for SiO₂.

Note that the gate electrode 114 serves as a back-gate electrode, and the gate insulating film 118 serves as a gate insulating film for the gate electrode 114.

Since the gate electrode 114 overlaps with the vicinity of an edge of the drain electrode 116b in the channel region, the transistor has a high controllability of threshold voltage. This is because an electric field of the drain electrode causes a depletion layer in the transistor to expand in the vicinity of the edge of the drain electrode 116b in the channel region. The expansion of the depletion layer may cause an increase in the off-state current of the transistor and a change in threshold voltage. An electric field of the gate electrode 114 overlapping with the vicinity of the edge of the drain electrode 116b in the channel region makes it possible to suppress the expansion of the depletion layer, and thus to suppress an increase in off-state current and to increase the controllability of threshold voltage.

In other words, when the gate electrode 114 overlaps with the vicinity of the edge of the drain electrode 116b in the channel region, an increase in off-state current can be suppressed and a high controllability of threshold voltage can be achieved.

Furthermore, since the gate electrode 114 overlaps with the drain electrode 116b and does not overlap with the source electrode 116a, parasitic capacitance can be reduced as compared to the case where a back-gate electrode overlaps with both a source electrode and a drain electrode. Accordingly, the operation speed of the transistor can be increased.

By thus providing the gate electrode 104, the gate electrode 114, the source electrode 116a, the drain electrode 116b, and the oxide semiconductor film 106, the transistor with a high controllability of threshold voltage and a high operation speed can be provided.

As the oxide semiconductor film 106, an In-M-Zn oxide film may be used, for example. Here, a metal element M is an element whose bond energy with oxygen is higher than that of In and that of Zn. Alternatively, M is an element which has a function of suppressing desorption of oxygen from the In-M-Zn oxide film. Owing to the effect of the metal element M, generation of oxygen vacancies in the oxide semiconductor film 106 is suppressed. Note that oxygen vacancies in the oxide semiconductor film 106 generate carriers in some cases. Therefore, the effect of the metal element M suppresses an increase in the carrier density of the oxide semiconductor film 106 and an increase in off-state current. Furthermore, a change in the electrical characteristics of the transistor, which is caused by oxygen vacancies, can be reduced, whereby a highly reliable transistor can be obtained.

The metal element M can be, specifically, Al, Sc, Ti, V, Cr, Mn, Fe, Co, Ni, Ga, Y, Zr, Nb, Mo, Sn, La, Ce, Pr, Nd, Sm, Eu, Gd, Tb, Dy, Ho, Er, Tm, Yb, Lu, Hf, Ta, or W, and is preferably Al, Ti, Ga, Y, Zr, Ce, or Hf. As the metal element M, one or more elements of the above elements may be selected. Further, Si or Ge may be used instead of the metal element M.

The hydrogen concentration in the oxide semiconductor film 106 is lower than or equal to 2×10²⁰ atoms/cm³, preferably lower than or equal to 5×10¹⁹ atoms/cm³, and more preferably lower than or equal to 1×10¹⁹ atoms/cm³. This is because hydrogen included in the oxide semiconductor film 106 generates unintentional carriers in some cases. The generated carriers might increase the off-state current of the transistor and vary the electrical characteristics of the transistor. Thus, when the hydrogen concentration in the oxide semiconductor film 106 is in the above range, an increase in the off-state current of the transistor and a change in the electrical characteristics of the transistor can be suppressed.

The oxide semiconductor film 106 may be in a non-single-crystal state, for example. The non-single-crystal state is, for example, structured by at least one of c-axis aligned crystal (CAAC), polycrystal, microcrystal, and an amorphous part. The density of defect states of an amorphous part is higher than those of microcrystal and CAAC. The density of defect states of microcrystal is higher than that of CAAC. Note that an oxide semiconductor including CAAC is referred to as a CAAC-OS (c-axis aligned crystalline oxide semiconductor).

For example, the oxide semiconductor film 106 may include a CAAC-OS. In the CAAC-OS, for example, c-axes are aligned, and a-axes and/or b-axes are not macroscopically aligned.

For example, the oxide semiconductor film 106 may include microcrystal. Note that an oxide semiconductor including microcrystal is referred to as a microcrystalline oxide semiconductor. A microcrystalline oxide semiconductor film includes microcrystal (also referred to as nanocrystal) with a size greater than or equal to 1 nm and less than 10 nm, for example. Alternatively, a microcrystalline oxide semiconductor film, for example, includes a crystal-amorphous mixed phase structure where crystal parts (each of which is greater than or equal to 1 nm and less than 10 nm) are distributed.

For example, the oxide semiconductor film 106 may include an amorphous part. Note that an oxide semiconductor including an amorphous part is referred to as an amorphous oxide semiconductor. An amorphous oxide semiconductor film, for example, has disordered atomic arrangement and no crystalline component. Alternatively, an amorphous oxide semiconductor film is, for example, absolutely amorphous and has no crystal part.

Note that the oxide semiconductor film 106 may be a mixed film including any of a CAAC-OS, a microcrystalline oxide semiconductor, and an amorphous oxide semiconductor. The mixed film, for example, includes a region of an amorphous oxide semiconductor, a region of a microcrystalline oxide semiconductor, and a region of a CAAC-OS. Further, the mixed film may have a stacked structure including a region of an amorphous oxide semiconductor, a region of a microcrystalline oxide semiconductor, and a region of a CAAC-OS, for example.

Note that the oxide semiconductor film 106 may be in a single-crystal state, for example.

The oxide semiconductor film 106 preferably includes a plurality of crystal parts. In each of the crystal parts, a c-axis is preferably aligned in a direction parallel to a normal vector of a surface where the oxide semiconductor film is formed or a normal vector of a surface of the oxide semiconductor film. Note that, among crystal parts, the directions of the a-axis and the b-axis of one crystal part may be different from those of another crystal part. An example of such an oxide semiconductor film is a CAAC-OS film.

The CAAC-OS film is not absolutely amorphous. The CAAC-OS film, for example, includes an oxide semiconductor with a crystal-amorphous mixed phase structure where crystal parts and amorphous parts are intermingled. Note that in most cases, the crystal part fits inside a cube whose one side is less than 100 nm In an image obtained with a transmission electron microscope (TEM), a boundary between an amorphous part and a crystal part and a boundary between crystal parts in the CAAC-OS film are not clearly detected. Further, with the TEM, a grain boundary in the CAAC-OS film is not clearly found. Thus, in the CAAC-OS film, a reduction in electron mobility due to the grain boundary is suppressed.

In each of the crystal parts included in the CAAC-OS film, for example, a c-axis is aligned in a direction parallel to a normal vector of a surface where the CAAC-OS film is formed or a normal vector of a surface of the CAAC-OS film. Further, in each of the crystal parts, metal atoms are arranged in a triangular or hexagonal configuration when seen from the direction perpendicular to the a-b plane, and metal atoms are arranged in a layered manner or metal atoms and oxygen atoms are arranged in a layered manner when seen from the direction perpendicular to the c-axis. Note that, among crystal parts, the directions of the a-axis and the b-axis of one crystal part may be different from those of another crystal part. In this specification, a term “perpendicular” includes a range from 80° to 100°, preferably from 85° to 95°. In addition, a term “parallel” includes a range from −10° to 10°, preferably from −5° to 5.

In the CAAC-OS film, distribution of crystal parts is not necessarily uniform. For example, in the formation process of the CAAC-OS film, in the case where crystal growth occurs from a surface side of the oxide semiconductor film, the proportion of crystal parts in the vicinity of the surface of the oxide semiconductor film is higher than that in the vicinity of the surface where the oxide semiconductor film is formed in some cases. Further, when an impurity is added to the CAAC-OS film, the crystal part in a region to which the impurity is added becomes amorphous in some cases.

Since the c-axes of the crystal parts included in the CAAC-OS film are aligned in the direction parallel to a normal vector of a surface where the CAAC-OS film is formed or a normal vector of a surface of the CAAC-OS film, the directions of the c-axes may be different from each other depending on the shape of the CAAC-OS film (the cross-sectional shape of the surface where the CAAC-OS film is formed or the cross-sectional shape of the surface of the CAAC-OS film). Note that the film deposition is accompanied with the formation of the crystal parts or followed by the formation of the crystal parts through crystallization treatment such as heat treatment. Hence, the c-axes of the crystal parts are aligned in the direction parallel to a normal vector of the surface where the CAAC-OS film is formed or a normal vector of the surface of the CAAC-OS film.

In a transistor using the CAAC-OS film, change in electrical characteristics due to irradiation with visible light or ultraviolet light is small. Thus, the transistor has high reliability.

In the oxide semiconductor film 106, the band gap is approximately 2.8 eV to 3.2 eV, the density of minority carriers is as extremely low as approximately 10⁻⁹ carriers/cm³, and majority carriers flow only from a source of a transistor.

The oxide semiconductor film 106 has a wider band gap than silicon by approximately 1 eV to 2 eV. For that reason, in the transistor including the oxide semiconductor film 106, impact ionization is unlikely to occur and avalanche breakdown is unlikely to occur. That is, it can be said that, in the transistor including the oxide semiconductor film 106, hot-carrier degradation is unlikely to occur.

Furthermore, carriers are unlikely to be generated in the aforementioned oxide semiconductor film 106; accordingly, in the transistor including the oxide semiconductor film 106, the channel region can be completely depleted by an electric field of the gate electrode 104 even in the case where the oxide semiconductor film 106 has a large thickness (for example, greater than or equal to 15 nm and less than 100 nm). For that reason, in the transistor including the oxide semiconductor film 106, an increase in off-state current and a change in threshold voltage due to a punch-through phenomenon are not caused. When the channel length is, for example, 3 μm, the off-state current can be lower than 10⁻²¹ A or lower than 10⁻²⁴ A per micrometer of channel width at room temperature.

The oxygen vacancies in the oxide semiconductor film, which are a factor of generating carriers, can be evaluated by electron spin resonance (ESR). That is, an oxide semiconductor film with few oxygen vacancies can be referred to as an oxide semiconductor film which does not have a signal due to oxygen vacancies evaluated by ESR. Specifically, the spin density attributed to oxygen vacancies in the oxide semiconductor film is lower than 5×10¹⁶ spins/cm³. When the oxide semiconductor film has oxygen vacancies, a signal having symmetry is found at a g value of around 1.93 in ESR.

There is no particular limitation on the substrate 100 as long as it has heat resistance enough to withstand at least heat treatment performed later. For example, a glass substrate, a ceramic substrate, a quartz substrate, or a sapphire substrate may be used as the substrate 100. Alternatively, a single crystal semiconductor substrate or a polycrystalline semiconductor substrate made of silicon, silicon carbide, or the like, a compound semiconductor substrate made of silicon germanium or the like, a silicon-on-insulator (SOI) substrate, or the like may be used. Still alternatively, any of these substrates provided with a semiconductor element may be used as the substrate 100.

In the case of using a large glass substrate such as the fifth generation (1000 mm×1200 mm or 1300 mm×1500 mm); the sixth generation (1500 mm×1800 mm); the seventh generation (1870 mm×2200 mm); the eighth generation (2200 mm×2500 mm); the ninth generation (2400 mm×2800 mm); or the tenth generation (2880 mm×3130 mm) as the substrate 100, microfabrication is difficult in some cases due to the shrinkage of the substrate 100, which is caused by heat treatment or the like in a manufacturing process of the semiconductor device. Therefore, in the case where the above-described large glass substrate is used as the substrate 100, a substrate which is unlikely to shrink through the heat treatment is preferably used. For example, a large-sized glass substrate which has a shrinkage of 10 ppm or less, preferably 5 ppm or less, and more preferably 3 ppm or less after heat treatment at 400° C., preferably at 450° C., and more preferably 500° C. for one hour may be used as the substrate 100.

Further alternatively, a flexible substrate may be used as the substrate 100. Note that as a method for forming a transistor over a flexible substrate, there is a method in which, after a transistor is formed over a non-flexible substrate, the transistor is separated from the non-flexible substrate and transferred to the substrate 100 which is a flexible substrate. In that case, a separation layer is preferably provided between the non-flexible substrate and the transistor.

The base insulating film 102 is provided in order that an impurity due to the substrate 100 is prevented from affecting the oxide semiconductor film 106. Note that in the case where the substrate 100 does not include an impurity, the base insulating film 102 is not necessarily provided. Further, in the case where diffusion of an impurity can be prevented by the gate insulating film 112, the base insulating film 102 is not necessarily provided.

Note that the base insulating film 102 is preferably an insulating film containing excess oxygen.

Although the base insulating film 102 is not in contact with the channel region of the oxide semiconductor film 106, oxygen can be supplied from the base insulating film 102 through the gate insulating film 112, for example. Therefore, in the case where the base insulating film 102 is an insulating film containing excess oxygen, oxygen vacancies in the oxide semiconductor film 106 can be reduced.

An insulating film containing excess oxygen refers to an insulating film in which the amount of released oxygen which is converted into oxygen atoms is greater than or equal to 1×10¹⁸ atoms/cm³, greater than or equal to 1×10¹⁹ atoms/cm³, or greater than or equal to 1×10²⁰ atoms/cm³ in thermal desorption spectroscopy (TDS).

Here, a method for measuring the amount of released oxygen using TDS is described.

The total amount of released gas in TDS is proportional to the integral value of the ion intensity of the released gas. Then, this integral value is compared with the reference value of a standard sample, whereby the total amount of the released gas can be calculated.

For example, the number of released oxygen molecules (N_{O2}) from an insulating film can be calculated according to Formula (I) using the TDS results of a silicon wafer containing hydrogen at a predetermined density, which is the standard sample, and the TDS results of the insulating film. Here, all gasses having a mass number of 32 which are obtained by the TDS are assumed to originate from an oxygen molecule. CH₃OH can also be given as a gas having a mass number of 32, but is not taken into consideration on the assumption that CH₃OH is unlikely to be present. Further, an oxygen molecule including an oxygen atom having a mass number of 17 or 18, which is an isotope of an oxygen atom, is also not taken into consideration because the proportion of such a molecule in the natural world is minimal.

$$\begin{matrix}[ FORMULA 1 ] & \\ {N}_{O 2} = \frac{{N}_{H 2}}{{S}_{H 2}} \times {S}_{O 2} \times α & ( 1 )\end{matrix}$$

N_{H2} is a value obtained by conversion of the number of hydrogen molecules desorbed from the standard sample into density. S_{H2} is an integral value of ion intensity when the standard sample is analyzed by TDS. Here, the reference value of the standard sample is expressed by N_{H2}/S_{H2}. S_{O2} is an integral value of ion intensity when the insulating film is analyzed by TDS, and α is a coefficient affecting the ion intensity in the TDS. For the details of Formula (I), Japanese Published Patent Application No. H6-275697 is referred to. Note that the amount of released oxygen from the insulating film was measured with a thermal desorption spectroscopy apparatus produced by ESCO Ltd., EMD-WA1000S/W using a silicon wafer containing hydrogen atoms at 1×10¹⁶ atoms/cm² as the standard sample.

Further, in the TDS, oxygen is partly detected as an oxygen atom. The ratio between oxygen molecules and oxygen atoms can be calculated from the ionization rate of oxygen molecules. Note that, since the above α is determined considering the ionization rate of oxygen molecules, the number of released oxygen atoms can be estimated through the evaluation of the number of the released oxygen molecules.

Note that N_{O2} is the number of released oxygen molecules. When the number of released oxygen molecules is converted into the number of released oxygen atoms, the number of released oxygen atoms is twice the number of released oxygen molecules.

The insulating film containing excess oxygen may contain a peroxide radical. Specifically, the spin density attributed to a peroxide radical of the insulating film is higher than or equal to 5×10¹⁷ spins/cm³. Note that the insulating film containing a peroxide radical has a signal having asymmetry at a g value of around 2.01 in ESR.

The insulating film containing excess oxygen may be formed using oxygen-excess silicon oxide (SiOₓ (X>2)). In the oxygen-excess silicon oxide (SiOₓ (X>2)), the number of oxygen atoms per unit volume is more than twice the number of silicon atoms per unit volume. The number of silicon atoms and the number of oxygen atoms per unit volume are measured by Rutherford backscattering spectrometry.

The base insulating film 102 may be formed of a single layer or a stacked layer using one or more of insulating films including the following materials: aluminum oxide, aluminum nitride, magnesium oxide, silicon oxide, silicon oxynitride, germanium oxide, yttrium oxide, zirconium oxide, lanthanum oxide, neodymium oxide, hafnium oxide, and tantalum oxide. Silicon nitride oxide or silicon nitride may be stacked over the single layer or the stacked layer.

The amount of oxygen is larger than that of nitrogen in silicon oxynitride, and the amount of nitrogen is larger than that of oxygen in silicon nitride oxide.

The gate electrode 104 may be formed of a single layer or a stacked layer of a simple substance selected from Al, Ti, Cr, Co, Ni, Cu, Y, Zr, Mo, Ag, Ta, and W; a nitride containing one or more kinds of the above substances; an oxide containing one or more kinds of the above substances; or an alloy containing one or more kinds of the above substances.

The gate insulating film 112 is preferably an insulating film containing excess oxygen.

In the case where the gate insulating film 112 is an insulating film containing excess oxygen, oxygen vacancies in the oxide semiconductor film 106 can be reduced.

The gate insulating film 112 may be formed of a single layer or a stacked layer using one or more of insulating films including the following materials: aluminum oxide, magnesium oxide, silicon oxide, silicon oxynitride, silicon nitride oxide, silicon nitride, germanium oxide, yttrium oxide, zirconium oxide, lanthanum oxide, neodymium oxide, hafnium oxide, and tantalum oxide.

The source electrode 116a and the drain electrode 116b may be formed of a single layer or a stacked layer of a simple substance selected from Al, Ti, Cr, Co, Ni, Cu, Y, Zr, Mo, Ag, Ta, and W; a nitride containing one or more kinds of the above substances; an oxide containing one or more kinds of the above substances; or an alloy containing one or more kinds of the above substances. Note that the source electrode 116a and the drain electrode 116b may be formed using the same conductive film or different conductive films.

The gate insulating film 118 is preferably an insulating film containing excess oxygen.

In the case where the gate insulating film 118 is an insulating film containing excess oxygen, oxygen vacancies in the oxide semiconductor film 106 can be reduced.

The gate insulating film 118 may be formed of a single layer or a stacked layer using one or more of insulating films including the following materials: aluminum oxide, magnesium oxide, silicon oxide, silicon oxynitride, silicon nitride oxide, silicon nitride, germanium oxide, yttrium oxide, zirconium oxide, lanthanum oxide, neodymium oxide, hafnium oxide, and tantalum oxide.

The gate electrode 114 may be formed of a single layer or a stacked layer of a simple substance selected from Al, Ti, Cr, Co, Ni, Cu, Y, Zr, Mo, Ag, Ta, and W; a nitride containing one or more kinds of the above substances; an oxide containing one or more kinds of the above substances; or an alloy containing one or more kinds of the above substances.

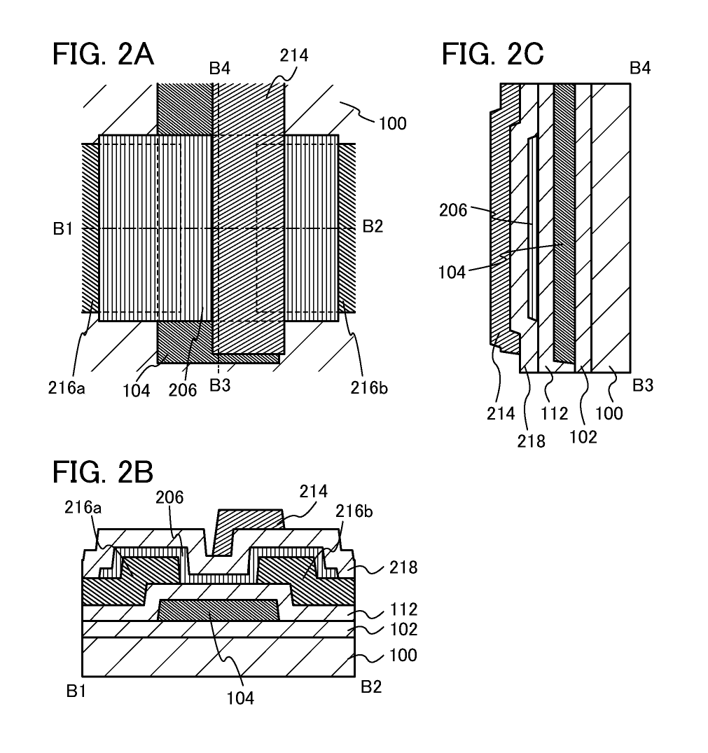

Next, a transistor having a structure different from that in FIGS. 1A to 1C will be described with reference to FIGS. 2A to 2C.

FIG. 2A is a top view of a transistor of one embodiment of the present invention. FIG. 2B is a cross-sectional view along dashed-dotted line B1-B2 of FIG. 2A. FIG. 2C is a cross-sectional view along dashed-dotted line B3-B4 of FIG. 2A. Note that the base insulating film 102 and the like are not illustrated in FIG. 2A for simplicity.

FIG. 2B is a cross-sectional view of a transistor including the base insulating film 102 over the substrate 100, the gate electrode 104 over the base insulating film 102, the gate insulating film 112 over the gate electrode 104, a source electrode 216a and a drain electrode 216b which are over the gate insulating film 112, an oxide semiconductor film 206 which is over the gate insulating film 112, the source electrode 216a, and the drain electrode 216b and overlaps with the gate electrode 104, a gate insulating film 218 over the oxide semiconductor film 206, the source electrode 216a, and the drain electrode 216b, and a gate electrode 214 which is over the gate insulating film 218, overlaps with the oxide semiconductor film 206 and the drain electrode 216b, and does not overlap with the source electrode 216a.

Note that in the oxide semiconductor film 206, a region overlapping with the gate electrode 104 and interposed between the source electrode 216a and the drain electrode 216b is a channel region. Thus, the center of the channel region is at the same distance from the source electrode 216a and the drain electrode 216b. Accordingly, in FIGS. 2A to 2C, dashed-dotted line B3-B4 passes through the center of the channel region.

Here, the gate electrode 104 overlaps with the source electrode 216a and the drain electrode 216b. On the other hand, the gate electrode 214 overlaps with the center of the channel region. Moreover, a region where the gate electrode 214 overlaps with the drain electrode 216b has a width of 1 μm to 3 μm in a channel length direction.

The gate insulating film 218 has an equivalent oxide thickness larger than that of the gate insulating film 112.

Note that the gate electrode 214 serves as a back-gate electrode, and the gate insulating film 218 serves as a gate insulating film for the gate electrode 214.

Since the gate electrode 214 overlaps with the vicinity of an edge of the drain electrode 216b in the channel region, the transistor has a high controllability of threshold voltage. An electric field of the gate electrode 214 overlapping with the vicinity of the edge of the drain electrode 216b in the channel region makes it possible to suppress the expansion of the depletion layer which is due to an electric field of the drain electrode 216b, and thus to suppress an increase in off-state current and to increase the controllability of threshold voltage.

In other words, when the gate electrode 214 overlaps with the vicinity of the edge of the drain electrode 216b in the channel region, an increase in off-state current can be suppressed and a high controllability of threshold voltage can be achieved.

Furthermore, since the gate electrode 214 overlaps with the drain electrode 216b and does not overlap with the source electrode 216a, parasitic capacitance can be reduced as compared to the case where a back-gate electrode overlaps with both a source electrode and a drain electrode. Accordingly, the operation speed of the transistor can be increased.

By thus providing the gate electrode 104, the gate electrode 214, the source electrode 216a, the drain electrode 216b, and the oxide semiconductor film 206, the transistor with a high controllability of threshold voltage and a high operation speed can be provided.

Here, the description of FIGS. 1A to 1C is referred to for the substrate 100, the base insulating film 102, the gate electrode 104, and the gate insulating film 112.

The source electrode 216a and the drain electrode 216b may be formed using any of the conductive films used for the source electrode 116a and the drain electrode 116b.

The oxide semiconductor film 206 may be formed using any of the oxide semiconductor films used for the oxide semiconductor film 106.

The gate insulating film 218 may be formed using any of the insulating films used for the gate insulating film 118.

The gate electrode 214 may be formed using any of the conductive films used for the gate electrode 114.

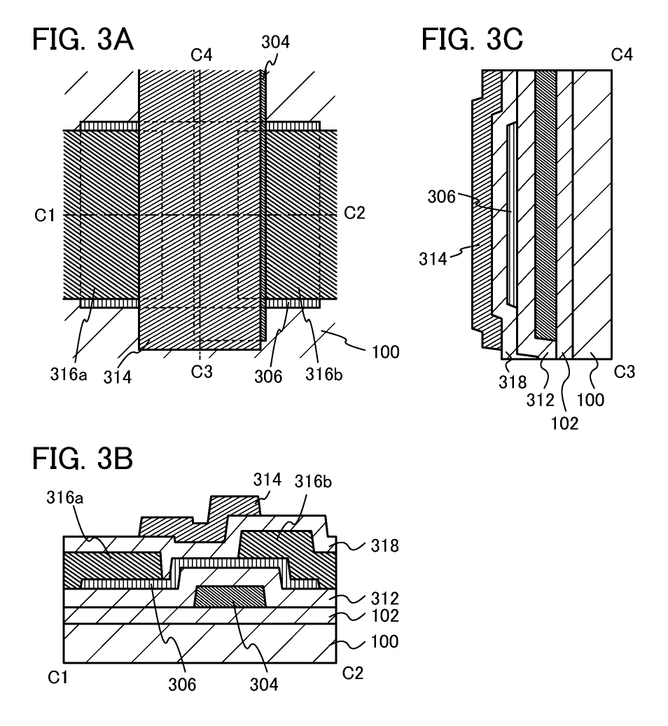

Next, a transistor having a structure different from those in FIGS. 1A to 1C and FIGS. 2A to 2C will be described with reference to FIGS. 3A to 3C.

FIG. 3A is a top view of a transistor of one embodiment of the present invention. FIG. 3B is a cross-sectional view along dashed-dotted line C1-C2 of FIG. 3A. FIG. 3C is a cross-sectional view along dashed-dotted line C3-C4 of FIG. 3A. Note that the base insulating film 102 and the like are not illustrated in FIG. 3A for simplicity.

FIG. 3B is a cross-sectional view of a transistor including the base insulating film 102 over the substrate 100, a gate electrode 304 over the base insulating film 102, a gate insulating film 312 over the gate electrode 304, an oxide semiconductor film 306 which is over the gate insulating film 312 and overlaps with the gate electrode 304, a source electrode 316a which is over the oxide semiconductor film 306 and does not overlap with the gate electrode 304, a drain electrode 316b which is over the oxide semiconductor film 306 and overlaps with the gate electrode 304, a gate insulating film 318 over the oxide semiconductor film 306, the source electrode 316a, and the drain electrode 316b, and a gate electrode 314 which is over the gate insulating film 318 and overlaps with the oxide semiconductor film 306.

Note that in the oxide semiconductor film 306, a region overlapping with the gate electrode 314 and interposed between the source electrode 316a and the drain electrode 316b is a channel region. Thus, the center of the channel region is at the same distance from the source electrode 316a and the drain electrode 316b. Accordingly, in FIGS. 3A to 3C, dashed-dotted line C3-C4 passes through the center of the channel region.

Here, the gate electrode 314 overlaps with the source electrode 316a and the drain electrode 316b. On the other hand, the gate electrode 304 overlaps with the center of the channel region. Moreover, a region where the gate electrode 304 overlaps with the drain electrode 316b has a width of 1 μm to 3 μm in a channel length direction.

The gate insulating film 312 has an equivalent oxide thickness larger than that of the gate insulating film 318.

Note that the gate electrode 304 serves as a back-gate electrode, and the gate insulating film 312 serves as a gate insulating film for the gate electrode 304.

Since the gate electrode 304 overlaps with the vicinity of an edge of the drain electrode 316b in the channel region, the transistor has a high controllability of threshold voltage. An electric field of the gate electrode 304 overlapping with the vicinity of the edge of the drain electrode 316b in the channel region makes it possible to suppress the expansion of the depletion layer which is due to an electric field of the drain electrode 316b, and thus to suppress an increase in off-state current and to increase the controllability of threshold voltage.

In other words, when the gate electrode 304 overlaps with the vicinity of the edge of the drain electrode 316b in the channel region, an increase in off-state current can be suppressed and a high controllability of threshold voltage can be achieved.

Furthermore, since the gate electrode 304 overlaps with the drain electrode 316b and does not overlap with the source electrode 316a, parasitic capacitance can be reduced as compared to the case where a back-gate electrode overlaps with both a source electrode and a drain electrode. Accordingly, the operation speed of the transistor can be increased.

By thus providing the gate electrode 304, the gate electrode 314, the source electrode 316a, the drain electrode 316b, and the oxide semiconductor film 306, the transistor with a high controllability of threshold voltage and a high operation speed can be provided.

Here, the description of FIGS. 1A to 1C is referred to for the substrate 100 and the base insulating film 102.

The gate electrode 304 may be formed using any of the conductive films used for the gate electrode 114.

The gate insulating film 312 may be formed using any of the insulating films used for the gate insulating film 118.

The oxide semiconductor film 306 may be formed using any of the oxide semiconductor films used for the oxide semiconductor film 106.

The source electrode 316a and the drain electrode 316b may be formed using any of the conductive films used for the source electrode 116a and the drain electrode 116b.

The gate insulating film 318 may be formed using any of the insulating films used for the gate insulating film 112.

The gate electrode 314 may be formed using any of the conductive films used for the gate electrode 104.

Next, a transistor having a structure different from those in FIGS. 1A to 1C,

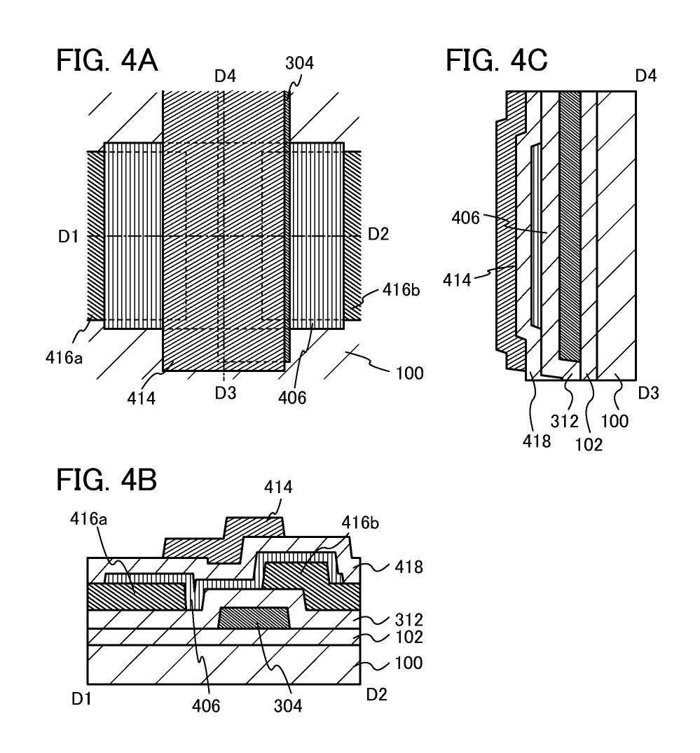

FIGS. 2A to 2C, and FIGS. 3A to 3C will be described with reference to FIGS. 4A to 4C.

FIG. 4A is a top view of a transistor of one embodiment of the present invention. FIG. 4B is a cross-sectional view along dashed-dotted line D1-D2 of FIG. 4A. FIG. 4C is a cross-sectional view along dashed-dotted line D3-D4 of FIG. 4A. Note that the base insulating film 102 and the like are not illustrated in FIG. 4A for simplicity.

FIG. 4B is a cross-sectional view of a transistor including the base insulating film 102 over the substrate 100, the gate electrode 304 over the base insulating film 102, the gate insulating film 312 over the gate electrode 304, a source electrode 416a and a drain electrode 416b which are over the gate insulating film 312, an oxide semiconductor film 406 which is over the gate insulating film 312, the source electrode 416a, and the drain electrode 416b and overlaps with the gate electrode 304, a gate insulating film 418 over the oxide semiconductor film 406, and a gate electrode 414 which is over the gate insulating film 418 and overlaps with the oxide semiconductor film 406.

Note that in the oxide semiconductor film 406, a region overlapping with the gate electrode 414 and interposed between the source electrode 416a and the drain electrode 416b is a channel region. Thus, the center of the channel region is at the same distance from the source electrode 416a and the drain electrode 416b. Accordingly, in FIGS. 4A to 4C, dashed-dotted line D3-D4 passes through the center of the channel region.

Here, the gate electrode 414 overlaps with the source electrode 416a and the drain electrode 416b. On the other hand, the gate electrode 304 overlaps with the center of the channel region. Moreover, a region where the gate electrode 304 overlaps with the drain electrode 416b has a width of 1 μm to 3 μm in a channel length direction.

The gate insulating film 312 has an equivalent oxide thickness larger than that of the gate insulating film 418.

Note that the gate electrode 304 serves as a back-gate electrode, and the gate insulating film 312 serves as a gate insulating film for the gate electrode 304.

Since the gate electrode 304 overlaps with the vicinity of an edge of the drain electrode 416b in the channel region, the transistor has a high controllability of threshold voltage. An electric field of the gate electrode 304 overlapping with the vicinity of the edge of the drain electrode 416b in the channel region makes it possible to suppress the expansion of the depletion layer which is due to an electric field of the drain electrode 416b, and thus to suppress an increase in off-state current and to increase the controllability of threshold voltage.

In other words, when the gate electrode 304 overlaps with the vicinity of the edge of the drain electrode 416b in the channel region, an increase in off-state current can be suppressed and a high controllability of threshold voltage can be achieved.

Furthermore, since the gate electrode 304 overlaps with the drain electrode 416b and does not overlap with the source electrode 416a, parasitic capacitance can be reduced as compared to the case where a back-gate electrode overlaps with a source electrode and a drain electrode. Accordingly, the operation speed of the transistor can be increased.

By thus providing the gate electrode 304, the gate electrode 414, the source electrode 416a, the drain electrode 416b, and the oxide semiconductor film 406, the transistor with a high controllability of threshold voltage and a high operation speed can be provided.

Here, the description of FIGS. 1A to 1C is referred to for the substrate 100 and the base insulating film 102, and the description of FIGS. 3A to 3C is referred to for the gate electrode 304 and the gate insulating film 312.

The source electrode 416a and the drain electrode 416b may be formed using any of the conductive films used for the source electrode 116a and the drain electrode 116b.

The oxide semiconductor film 406 may be formed using any of the oxide semiconductor films used for the oxide semiconductor film 106.

The gate insulating film 418 may be formed using any of the insulating films used for the gate insulating film 112.

The gate electrode 414 may be formed using any of the conductive films used for the gate electrode 104.

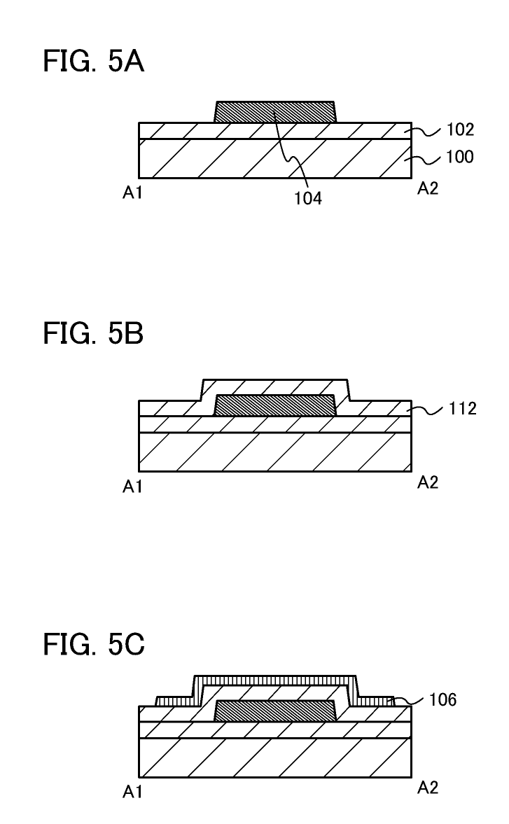

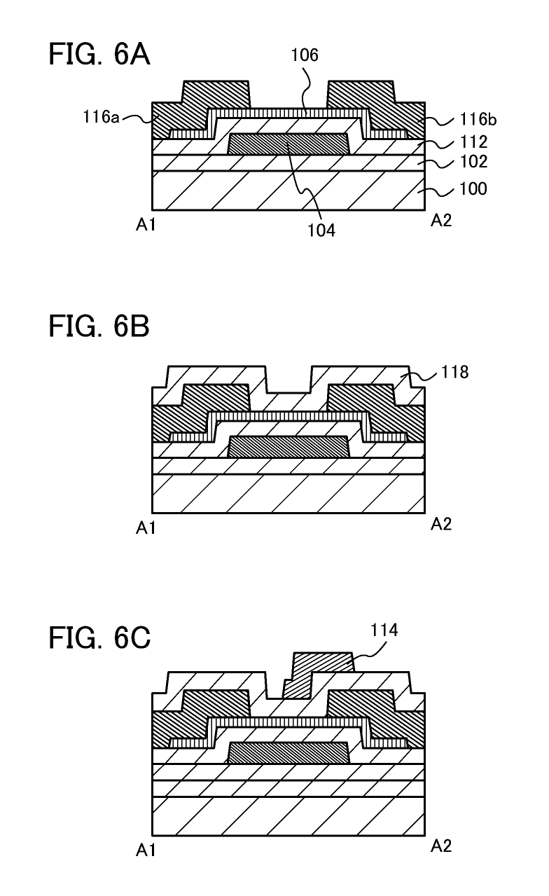

Next, a method for manufacturing the transistor illustrated in FIGS. 1A to 1C will be described with reference to FIGS. 5A to 5C and FIGS. 6A to 6C. Note that for simplicity, FIGS. 5A to 5C and FIGS. 6A to 6C only illustrate cross-sectional views of the transistor corresponding to FIG. 1B. Further, methods for manufacturing the transistors illustrated in FIGS. 2A to 2C, FIGS. 3A to 3C, and FIGS. 4A to 4C are omitted because the description of FIGS. 5A to 5C and FIGS. 6A to 6C can be referred to for the methods.

First, the substrate 100 is prepared. The substrate 100 may be formed using any of the aforementioned materials for the substrate 100.

Next, the base insulating film 102 is deposited. The base insulating film 102 may be formed using any of the above materials for the base insulating film 102 by a sputtering method, a chemical vapor deposition (CVD) method, a molecular beam epitaxy (MBE) method, an atomic layer deposition (ALD) method, or a pulsed laser deposition (PLD) method.

Then, a conductive film serving as the gate electrode 104 is deposited. The conductive film serving as the gate electrode 104 may be formed using any of the above materials for the gate electrode 104 by a sputtering method, a CVD method, an MBE method, an ALD method, or a PLD method.

After that, the conductive film serving as the gate electrode 104 is processed, so that the gate electrode 104 is formed (see FIG. 5A).

Next, the gate insulating film 112 is deposited (see FIG. 5B). The gate insulating film 112 may be formed using any of the above insulating films used for the gate insulating film 112 by a sputtering method, a CVD method, an MBE method, an ALD method, or a PLD method.

Then, an oxide semiconductor film serving as the oxide semiconductor film 106 is deposited. The oxide semiconductor film serving as the oxide semiconductor film 106 may be formed using any of the above oxide semiconductor films used for the oxide semiconductor film 106 by a sputtering method, a CVD method, an MBE method, an ALD method, or a PLD method.

First heat treatment may be performed after the deposition of the oxide semiconductor film serving as the oxide semiconductor film 106. The first heat treatment may be performed at a temperature higher than or equal to 250° C. and lower than or equal to 650° C., preferably higher than or equal to 300° C. and lower than or equal to 500° C. The first heat treatment is performed in an inert gas atmosphere, in an atmosphere containing an oxidizing gas at 10 ppm or more, 1% or more, or 10% or more, or under reduced pressure. Alternatively, the first heat treatment may be performed in such a manner that heat treatment is performed in an inert gas atmosphere, and then another heat treatment is performed in an atmosphere containing an oxidizing gas at 10 ppm or more, 1% or more, or 10% or more in order to compensate desorbed oxygen. Through the first heat treatment, impurities such as hydrogen and water can be removed from the oxide semiconductor film serving as the oxide semiconductor film 106.

Next, the oxide semiconductor film serving as the oxide semiconductor film 106 is processed into the island-shaped oxide semiconductor film 106 (see FIG. 5C).

Then, a conductive film serving as the source electrode 116a and the drain electrode 116b is deposited. The conductive film serving as the source electrode 116a and the drain electrode 116b may be formed using any of the above conductive films used for the source electrode 116a and the drain electrode 116b by a sputtering method, a CVD method, an MBE method, an ALD method, or a PLD method.

The conductive film serving as the source electrode 116a and the drain electrode 116b is processed so that the source electrode 116a and the drain electrode 116b are obtained (see FIG. 6A).

After that, the gate insulating film 118 is deposited (see FIG. 6B). The gate insulating film 118 may be formed using any of the above insulating films used for the gate insulating film 118 by a sputtering method, a CVD method, an MBE method, an ALD method, or a PLD method.

Then, a conductive film serving as the gate electrode 114 is deposited. The conductive film serving as the gate electrode 114 may be formed using any of the above conductive films used for the gate electrode 114 by a sputtering method, a CVD method, an MBE method, an ALD method, or a PLD method.

Then, the conductive film serving as the gate electrode 114 is processed so that the gate electrode 114 is obtained (see FIG. 6C). At this time, the gate electrode 114 may be formed to overlap with an edge of the drain electrode 116b in the channel region. In this embodiment, even when the gate electrode 114 serving as a back-gate electrode is somewhat misaligned, the controllability of threshold voltage is unlikely to decrease as long as the gate electrode 114 overlaps with the edge of the drain electrode 116b in the channel region. This is because a change in threshold voltage is mostly caused by a depletion layer in the vicinity of the edge of the drain electrode 116b in the channel region. Accordingly, this embodiment has an effect of reducing the influence of variation in the manufacture of transistors.

After that, second heat treatment may be performed. The second heat treatment may be performed under conditions selected from conditions similar to those of the first heat treatment. The second heat treatment allows reducing oxygen vacancies in the oxide semiconductor film 106.

In the aforementioned manner, the transistor illustrated in FIG. 1A to 1C can be manufactured.

According to this embodiment, it is possible to provide a transistor which is less likely to be affected by variation in the manufacture of transistors and has a high operation speed and a high controllability of threshold voltage.

This embodiment can be implemented in appropriate combination with any of the other embodiments and example.

### Embodiment 2

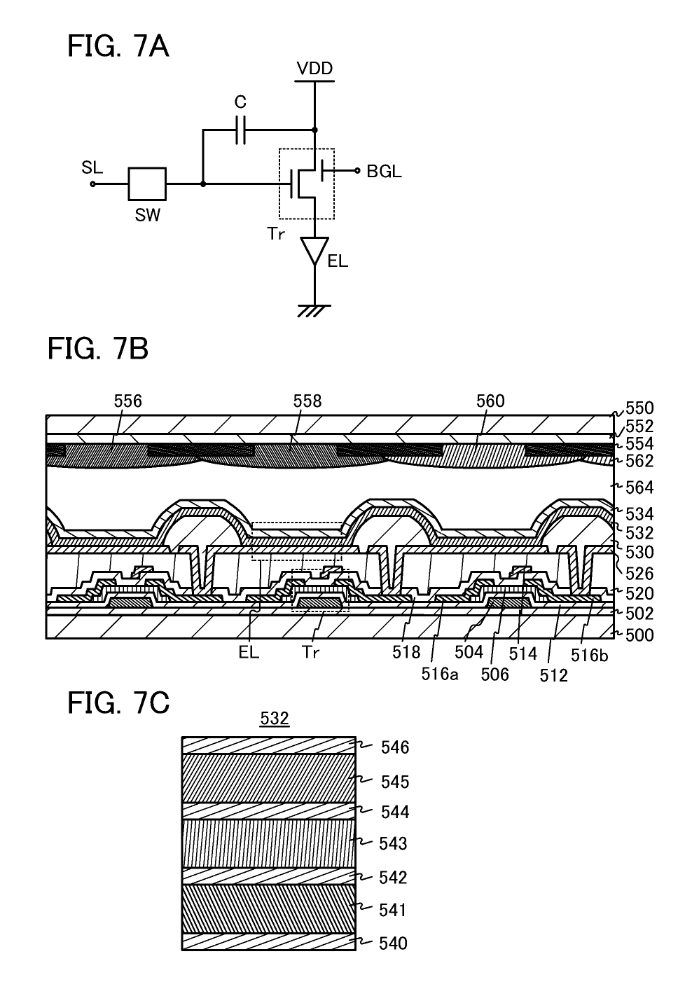

In this embodiment, an EL (electroluminescence) display device of one embodiment of the present invention will be described with reference to FIGS. 7A to 7C.

FIG. 7A is a part of a circuit diagram of the EL display device. The EL display device includes a transistor Tr, an element EL, a capacitor C, a switch SW, a signal line SL, and a back-gate line BGL.

The transistor shown in Embodiment 1 can be applied to the transistor Tr. The transistor shown in Embodiment 1 is suitable for a driving transistor in an EL display device because the transistor is less likely to be affected by variation in the manufacture of transistors and has a high operation speed and a high controllability of threshold voltage.

There is no particular limitation on the kinds of the capacitor C and the switch SW; a transistor is preferably used as the switch SW. In the case where a transistor is used as the switch SW, a gate line may be additionally provided for switching of the transistor. The transistor may be the transistor shown in Embodiment 1.

Here, a gate of the transistor Tr is connected to one terminal of the switch SW and one terminal of the capacitor C, a drain of the transistor Tr is connected to a power supply potential (VDD) and the other terminal of the capacitor C, and a source of the transistor Tr is electrically connected to one terminal of the element EL. Note that the transistor Tr includes a back-gate electrode which is electrically connected to a back-gate line BGL. Further, the other terminal of the switch SW is electrically connected to a signal line SL, and the other terminal of the element EL is grounded.

FIG. 7B is an example of a cross-sectional view of the EL display device. The EL display device illustrated in FIG. 7B includes a first substrate 500; a base insulating film 502 over the first substrate 500; a gate electrode 504 over the base insulating film 502; a gate insulating film 512 over the gate electrode 504; an oxide semiconductor film 506 which is over the gate insulating film 512 and overlaps with the gate electrode 504; a source electrode 516a and a drain electrode 516b which are over the oxide semiconductor film 506; a gate insulating film 518 over the oxide semiconductor film 506, the source electrode 516a, and the drain electrode 516b; a gate electrode 514 which is over the gate insulating film 518, overlaps with the oxide semiconductor film 506 and the drain electrode 516b, and does not overlap with the source electrode 516a; a planarization film 520 including openings which is over the gate insulating film 518 and the gate electrode 514; a plurality of first electrodes 526 which are in contact with the drain electrode 516b through the openings provided in the planarization film 520; partition walls 530 covering edges of the first electrodes 526; an organic EL layer 532 over the first electrodes 526 and the partition walls 530; a second electrode 534 over the organic EL layer 532; a coloring layer 556, a coloring layer 558, a coloring layer 560, a coloring layer 562, and a black matrix 554 between the coloring layers which are provided over the second electrode 534 with a space 564 interposed therebetween; an insulating film 552 over the black matrix 554, the coloring layer 556, the coloring layer 558, the coloring layer 560, and the coloring layer 562; and a second substrate 550 over the insulating film 552. Note that the insulating film 552 is not necessarily provided. Furthermore, the coloring layer 556, the coloring layer 558, the coloring layer 560, and the coloring layer 562 may be provided with an insulating film serving as a barrier film.

Here, an insulating film serving as a barrier film for the organic EL layer 532 may be provided over the second electrode 534.

Here, the space 564 may be filled with an organic compound having a light-transmitting property in a visible light region, such as an epoxy resin, or an inorganic compound. In addition, a drying agent, a spacer, or a sealant may be provided in the space 564 although they are not illustrated.

The transistor Tr includes the gate electrode 504, the gate insulating film 512 over the gate electrode 504, the oxide semiconductor film 506 which is over the gate insulating film 512 and overlaps with the gate electrode 504, the source electrode 516a and the drain electrode 516b which are over the oxide semiconductor film 506, the gate insulating film 518 over the oxide semiconductor film 506, the source electrode 516a, and the drain electrode 516b, and the gate electrode 514 which is over the gate insulating film 518, overlaps with the oxide semiconductor film 506 and the drain electrode 516b, and does not overlap with the source electrode 516a.

The gate electrode 504 may be formed using any of the conductive films used for the gate electrode 104 shown in Embodiment 1.

The gate insulating film 512 may be formed using any of the insulating films used for the gate insulating film 112 shown in Embodiment 1.

The oxide semiconductor film 506 may be formed using any of the oxide semiconductor films used for the oxide semiconductor film 106 shown in Embodiment 1.

The source electrode 516a and the drain electrode 516b may be formed using any of the conductive films used for the source electrode 116a and the drain electrode 116b shown in Embodiment 1.

The gate insulating film 518 may be formed using any of the insulating films used for the gate insulating film 118 shown in Embodiment 1.

The gate electrode 514 may be formed using any of the conductive films used for the gate electrode 114 shown in Embodiment 1. The threshold voltage of the transistor Tr can be controlled with the gate electrode 514.

Note that the transistor Tr has a structure similar to that of the transistor illustrated in FIGS. 1A to 1C; however, one embodiment of the present invention is not limited to this and the transistor Tr may have a structure similar to that of the transistor illustrated in FIGS. 2A to 2C, FIGS. 3A to 3C, or FIGS. 4A to 4C, for example.

The element EL includes the first electrode 526, the organic EL layer 532, and the second electrode 534.

The organic EL layer 532 may be a stack of plural kinds of light-emitting materials. For example, a structure illustrated in FIG. 7C may be employed. FIG. 7C illustrates a structure in which a first intermediate layer 540, a first light-emitting layer 541, a second intermediate layer 542, a second light-emitting layer 543, a third intermediate layer 544, a third light-emitting layer 545, and a fourth intermediate layer 546 are stacked in this order. In this case, materials emitting light of appropriate colors are preferably used for the first light-emitting layer 541, the second light-emitting layer 543, and the third light-emitting layer 545, because a light-emitting device with a high color rending property or higher emission efficiency can be formed.

Although the structure in which three light-emitting layers and four intermediate layers are provided is shown here, the number of light-emitting layers and the number of intermediate layers can be changed as appropriate. For example, the organic EL layer 532 can be formed with only the first intermediate layer 540, the first light-emitting layer 541, the second intermediate layer 542, the second light-emitting layer 543, and the third intermediate layer 544. Alternatively, the organic EL layer 532 may be formed with the first intermediate layer 540, the first light-emitting layer 541, the second intermediate layer 542, the second light-emitting layer 543, the third light-emitting layer 545, and the fourth intermediate layer 546, and the third intermediate layer 544 may be omitted.

Further, the intermediate layer may have a stacked-layer structure including any of a hole-injection layer, a hole-transport layer, an electron-transport layer, an electron-injection layer, and the like. Note that not all of these layers need to be provided as the intermediate layer. Depending on the need, a layer or layers can be selected as appropriate from these layers, and each layer can be provided in duplicate or more. Further, an electron-relay layer or the like may be added as appropriate as the intermediate layer, in addition to a carrier generation layer.

For the first electrode 526, a conductive film which efficiently reflects light emitted from the organic EL layer 532 is preferably used. Further, the first electrode 526 may have a stacked-layer structure. For example, it is preferable to use a conductive film including lithium, aluminum, titanium, magnesium, lanthanum, silver, silicon, or nickel.

The second electrode 534 is formed using a conductive film having a light-transmitting property in a visible light region. The conductive film having a light-transmitting property in a visible light region is, for example, indium oxide containing tungsten oxide, indium zinc oxide containing tungsten oxide, indium oxide containing titanium oxide, indium tin oxide containing titanium oxide, indium tin oxide (also referred to as ITO), indium zinc oxide, or ITO to which silicon oxide is added. Further, a metal thin film having a thickness small enough to transmit light (preferably, approximately 5 nm to 30 nm) can also be used. For example, a silver film, a magnesium film, or a silver-magnesium (Ag—Mg) alloy film each having a thickness of 5 nm can be used as the second electrode 534.

“Having a light-transmitting property in a visible light region” means that transmittance is higher than or equal to 80% in a visible light region.

Note that one of the first electrode 526 and the second electrode 534 functions as an anode, and the other functions as a cathode. It is preferable to use a conductive film having a high work function for the electrode which functions as an anode, and a conductive film having a low work function for the electrode which functions as a cathode. Note that in the case where a carrier generation layer is provided in contact with the anode, a variety of conductive films can be used for the anode regardless of their work functions.

The first substrate 500 may be formed using any of the materials of the substrate 100 shown in Embodiment 1.

For the first substrate 500, a material having flexibility and a high heat dissipation property is preferably used. For example, a metal material such as aluminum, titanium, nickel, copper, silver, SUS, or duralumin, or a metal alloy may be used with a thickness greater than or equal to 20 μm and less than or equal to 700 μm, preferably greater than or equal to 50 μm and less than or equal to 300 μm. Note that duralumin is a material having low corrosion resistance; therefore, the surface of duralumin is preferably coated with a material having high corrosion resistance.

The base insulating film 502 may be formed using any of the insulating films used for the base insulating film 102 shown in Embodiment 1.

The planarization film 520 may be formed using an organic compound or an inorganic compound. In the case of using an organic compound, for example, an acrylic resin, a polyimide resin, an epoxy resin, or a silicone resin may be used.

The partition wall 530 may be formed using an organic compound or an inorganic compound. In the case of using an organic compound, for example, an acrylic resin, a polyimide resin, an epoxy resin, or a silicone resin may be used.

Appropriate coloring layers are provided as the coloring layer 556, the coloring layer 558, the coloring layer 560, and the coloring layer 562, and for example, coloring layers of red, green, blue, and yellow, or coloring layers of red, green, blue, and white are selected. Although the four kinds of coloring layers are used in this embodiment, one embodiment of the present invention is not limited thereto and three or less kinds of coloring layers or five or more kinds of coloring layers may be used.

Note that the respective thicknesses of the coloring layers may be controlled so that color images are displayed with a higher color rending property.

In the EL display device described in this embodiment, color images can be displayed in such a manner that white light emitted from the element EL is radiated outside through the coloring layer 556, 558, 560, or 562. Note that the structure of the EL display device of one embodiment of the present invention is not limited to this. Specifically, color images may be displayed by providing plural kinds of elements ELs with different emission colors.

With such a structure in which color images are displayed using white light and coloring layers, a step of depositing light-emitting layers with different emission colors side by side is omitted for example, and it is thus possible to manufacture an EL display device with higher definition and reliability as compared to the case where light-emitting devices of the respective colors are arranged to form pixels.

The black matrix 554 is provided between the coloring layers in order to prevent color mixture between the coloring layers. The black matrix 554 is formed using at least one of metal materials such as titanium, tantalum, molybdenum, and tungsten; and a black resin, for example.

The insulating film 552 may be formed using the same insulating film as the base insulating film 502

The second substrate 550 may be formed using any of the materials of the substrate 100 shown in Embodiment 1. Note that it is preferable to use extremely thin glass with a thickness of 20 μm to 100 μm, for example, approximately 50 μm. When extremely thin glass is used as the second substrate 550, the second substrate 550 has flexibility to some extent in addition to low moisture permeability and therefore can have high resistance to bending and shock, which results in resistance to breakage, for example.

Alternatively, the second substrate 550 may be a stack body having flexibility and moisture impermeability, which includes two or more materials selected from silicon oxide, silicon oxynitride, silicon nitride oxide, silicon nitride, aluminum oxide, aluminum oxynitride, aluminum nitride oxide, aluminum nitride, silicon carbide, diamond-like carbon, or a high molecular material, which is provided over a resin or a sheet having a gas barrier property.

Since the second electrode 534, the insulating film 552, and the second substrate 550 each have a light-transmitting property in a visible light region, the EL display device shown in this embodiment has a so-called top emission structure, in which a light emission surface is on the second substrate 550 side.

Since a substrate having a high heat dissipation property is used for the first substrate 500, heat is easily released from the EL display device shown in this embodiment, whereby reduction in reliability due to heat can be suppressed.

In addition, by using the transistor having a high operation speed and a high controllability of threshold voltage, it becomes possible to provide an EL display device with a sufficiently high emission intensity and less variation in emission intensity.

This embodiment can be implemented in appropriate combination with any of the other embodiments and example.

### Embodiment 3

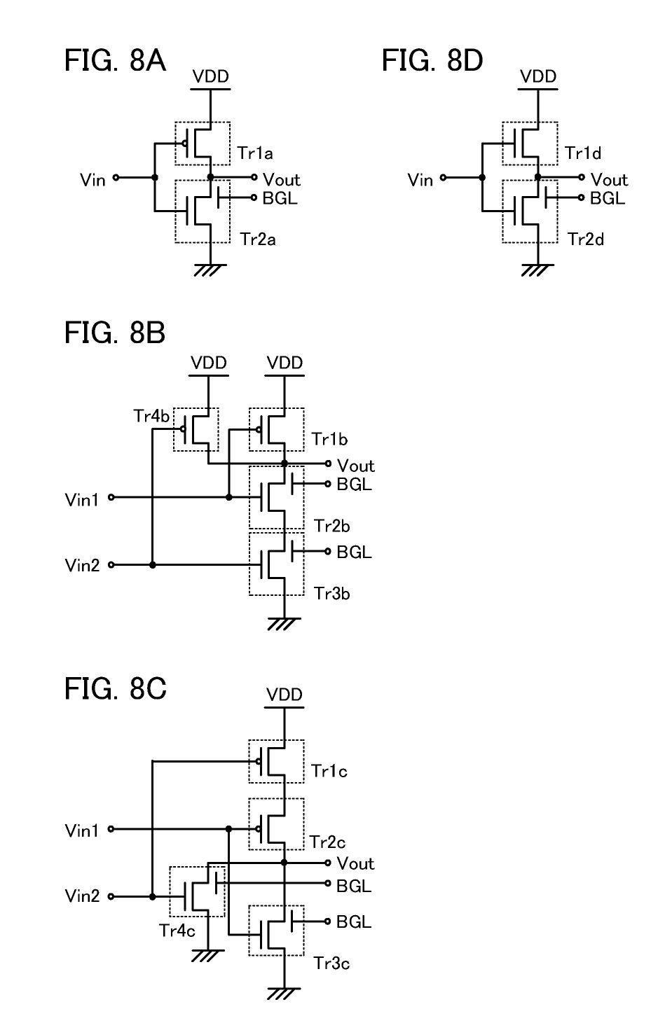

In this embodiment, an inverter of one embodiment of the present invention will be described with reference to FIGS. 8A to 8D.

FIG. 8A is a circuit diagram illustrating an example of an inverter using a p-channel transistor and an n-channel transistor.

A transistor Tr1a which is a p-channel transistor may be, for example, a transistor using silicon. Note that the transistor Tr1a is not limited to a transistor using silicon. The threshold voltage of the transistor Tr1a is denoted by Vth1a.

A transistor Tr2a which is an n-channel transistor may be, for example, the transistor shown in Embodiment 1. The threshold voltage of the transistor Tr2a is denoted by Vth2a.

Here, a gate of the transistor Tr1a is connected to an input terminal Vin and a gate of the transistor Tr2a. A source of the transistor Tr1a is electrically connected to a power supply potential (VDD). A drain of the transistor Tr1a is connected to a drain of the transistor Tr2a and an output terminal Vout. A source of the transistor Tr2a is connected to a ground potential (GND). A back-gate of the transistor Tr2a is connected to a back-gate line BGL.

For example, the threshold voltage Vth1a of the transistor Tr1a is higher than VDD with an inverted polarity and lower than 0 V (−VDD<Vth1a<0 V). Further, the threshold voltage Vth2a of the transistor Tr2a is higher than 0 V and lower than VDD (0 V<Vth2a<VDD).

Here, when the potential of the input terminal Vin is VDD, the gate voltage of the transistor Tr1a becomes 0 V so that the transistor Tr1a is turned off. Further, the gate voltage of the transistor Tr2a becomes VDD so that the transistor Tr2a is turned on. Accordingly, the output terminal Vout is electrically connected to GND and supplied with GND.

When the potential of the input terminal Vin is GND, the gate voltage of the transistor Tr1a becomes VDD so that the transistor Tr1a is turned on. Further, the gate voltage of the transistor Tr2a becomes 0 V so that the transistor Tr2a is turned off. Accordingly, the output terminal Vout is electrically connected to VDD and supplied with VDD.

As described above, in the circuit diagram of FIG. 8A, when the potential of the input terminal Vin is VDD, GND is output from the output terminal Vout, and when the potential of the input terminal Vin is GND, VDD is output from the output terminal Vout.

By applying the transistor shown in Embodiment 1 to the transistor Tr2a, a flow-through current when the transistor Tr2a is off can be significantly reduced because the transistor Tr2a has an extremely low off-state current. Thus, an inverter with low power consumption is achieved. Moreover, since the transistor Tr2a includes a back-gate with which the threshold voltage can be well controlled, the threshold voltage Vth2a can be set within a desired range and an increase in parasitic capacitance due to the back-gate can be suppressed, so that an inverter with a high operation speed is achieved.

Note that the inverters illustrated in FIG. 8A may be combined to form a NAND circuit illustrated in FIG. 8B. The circuit diagram of FIG. 8B includes a transistor Tr1b and a transistor Tr4b which are p-channel transistors, and a transistor Tr2b and a transistor Tr3b which are n-channel transistors. The transistors Tr1b and Tr4b may each be, for example, a transistor using silicon. The transistors Tr2b and Tr3b may each be, for example, the transistor shown in Embodiment 1.

The inverter illustrated in FIG. 8A may be combined to form a NOR circuit illustrated in FIG. 8C. The circuit diagram of FIG. 8C includes a transistor Tr1c and a transistor Tr2c which are p-channel transistors, and a transistor Tr3c and a transistor Tr4c which are n-channel transistors. The transistors Tr1c and Tr2c may each be, for example, a transistor using silicon. The transistors Tr3c and Tr4c may each be, for example, the transistor shown in Embodiment 1.

The aforementioned logic circuits are configured by the inverters using p-channel transistors and n-channel transistors; a logic circuit may be configured by an inverter using only n-channel transistors. FIG. 8D is a circuit diagram illustrating an example of an inverter using only n-channel transistors.

The circuit diagram of FIG. 8D includes a transistor Tr1d which is a depletion transistor and a transistor Tr2d which is an enhancement transistor.

The depletion transistor Tr1d may be, for example, a transistor using an oxide semiconductor film. Note that the transistor Tr1d is not limited to a transistor using an oxide semiconductor film, and may be, for example, a transistor using silicon. The threshold voltage of the transistor Tr2d is denoted by Vth1d. A resistor with a sufficiently low resistance may be provided instead of the depletion transistor.

The enhancement transistor Tr2d may be, for example, the transistor shown in Embodiment 1. The threshold voltage of the transistor Tr2d is denoted by Vth2d.

Note that the transistor shown in Embodiment 1 may be used as the transistor Tr1d. In that case, a transistor other than the transistor shown in Embodiment 1 may be used as the transistor Tr2d.

Here, a gate of the transistor Tr1d is connected to an input terminal Vin and a gate of the transistor Tr2d. A drain of the transistor Tr1d is electrically connected to VDD. A source of the transistor Tr1d is connected to a drain of the transistor Tr2d and an output terminal Vout. A source of the transistor Tr2d is connected to GND. A back-gate of the transistor Tr2d is connected to a back-gate line BGL.

The threshold voltage Vth1d of the transistor Tr1d is, for example, lower than 0 V (Vth1d<0 V). Accordingly, the transistor Tr1d is on regardless of the gate voltage, that is, the transistor Tr1d functions as a resistor having a sufficiently low resistance. Further, the threshold voltage Vth2d of the transistor Tr2d is higher than 0 V and lower than VDD (0 V<Vth2d<VDD). Note that a resistor having a sufficiently low resistance may be provided instead of the transistor Tr1d.

Note that the transistor Tr1d and the transistor Tr2d may be manufactured in the same process, which facilitates the production of the inverter. At this time, a back-gate is provided in at least one of the transistors Tr1d and Tr2d. In the case where the manufactured transistors are depletion transistors, the threshold voltage Vth2d may be set within the above range by the back-gate of the transistor Tr2d. In the case where the manufactured transistors are enhancement transistors, the threshold voltage Vth1d may be set within the above range by the back-gate of the transistor Tr1d. Note that the threshold voltages of the transistors Tr1d and Tr2d may be controlled by different back-gates.

Here, when the potential of the input terminal Vin is VDD, the gate voltage of the transistor Tr2d becomes VDD so that the transistor Tr2d is turned on. Accordingly, the output terminal Vout is electrically connected to GND and supplied with GND.

Further, when the potential of the input terminal Vin is GND, the gate voltage of the transistor Tr2d becomes 0 V so that the transistor Tr2d is turned off. Accordingly, the output terminal Vout is electrically connected to VDD and supplied with VDD. Note that strictly, the potential output from the output terminal Vout is equal to a potential dropped from VDD by the resistance of the transistor Tr1d. However, the effect of the voltage drop can be ignored because the resistance of the transistor Tr1d is sufficiently low.

As described above, in the circuit diagram of FIG. 8D, when the potential of the input terminal Vin is VDD, GND is output from the output terminal Vout, and when the potential of the input terminal Vin is GND, VDD is output from the output terminal Vout.

By applying the transistor shown in Embodiment 1 to the transistor Tr2d, a flow-through current when the transistor Tr2d is off can be significantly reduced because the transistor Tr2d has an extremely low off-state current. Thus, an inverter with low power consumption is achieved. Moreover, since the transistor Tr2d includes a back-gate with which the threshold voltage can be well controlled, the threshold voltage Vth2d can be set within a desired range and an increase in parasitic capacitance due to the back-gate can be suppressed, so that an inverter with a high operation speed is achieved.

This embodiment can be implemented in appropriate combination with any of the other embodiments and example.

### Embodiment 4

In this embodiment, a static random access memory (SRAM) will be described, the SRAM being a semiconductor device including a flip-flop which is obtained by applying the inverter circuit shown in Embodiment 3.

In the SRAM, data is retained using a flip-flop; therefore, unlike in a dynamic random access memory (DRAM), refresh operation is not necessary so that data can be retained with less power. In addition, the SRAM does not use a capacitor and thus is suitable for application requiring high-speed operation.

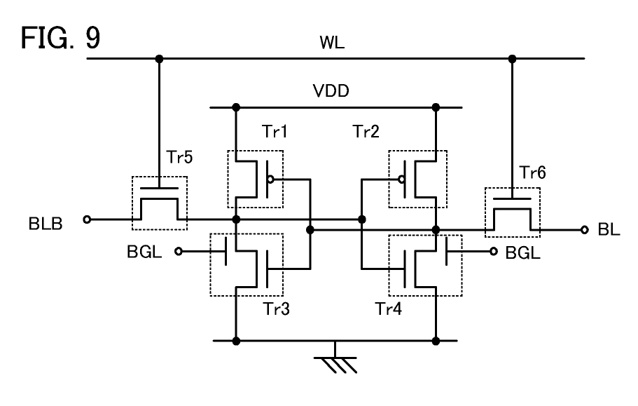

FIG. 9 is a circuit diagram equivalent to a memory cell of an SRAM of one embodiment of the present invention. Although only one memory cell is illustrated in FIG. 9, one embodiment of the present invention may be applied to a memory cell array including a plurality of the memory cells.

The memory cell illustrated in FIG. 9 includes a transistor Tr1, a transistor Tr2, a transistor Tr3, a transistor Tr4, a transistor Tr5, and a transistor Tr6. The transistors Tr1 and Tr2 are p-channel transistors, and the transistors Tr3 and Tr4 are n-channel transistors. A gate of the transistor Tr1 is electrically connected to a drain of the transistor Tr2, a gate of the transistor Tr3, a drain of the transistor Tr4, and one of a source and a drain of the transistor Tr6. A source of the transistor Tr1 is electrically connected to VDD. A drain of the transistor Tr1 is electrically connected to a gate of the transistor Tr2, a gate of the transistor Tr4, a drain of the transistor Tr3, and one of a source and a drain of the transistor Tr5. A source of the transistor Tr2 is electrically connected to VDD. A source of the transistor Tr3 is electrically connected to GND. A back-gate of the transistor Tr3 is electrically connected to a back-gate line BGL. A source of the transistor Tr4 is electrically connected to GND. A back-gate of the transistor Tr4 is electrically connected to a back-gate line BGL. A gate of the transistor Tr5 is electrically connected to a word line WL. The other of the source and the drain of the transistor Tr5 is electrically connected to a bit line BLB. A gate of the transistor Tr6 is electrically connected to the word line WL. The other of the source and the drain of the transistor Tr6 is electrically connected to a bit line BL.

Note that this embodiment shows an example where n-channel transistors are used as the transistors Tr5 and Tr6. However, the transistors Tr5 and Tr6 are not limited to n-channel transistors and may be p-channel transistors. In that case, writing, retaining, and reading methods described below may be changed as appropriate.

A flip-flop is thus configured in such a manner that an inverter including the transistors Tr1 and Tr3 and an inverter including the transistors Tr2 and Tr4 are connected in a ring.

The p-channel transistors may be, but are not limited to, transistors using silicon for example. The n-channel transistors may each be the transistor shown in Embodiment 1, or the like.

In this embodiment, the transistor shown in Embodiment 1 is applied to the transistors Tr3 and Tr4. Since the threshold voltage of the transistor is controlled by the back-gate, the transistor can be surely turned on or off. In addition, with an extremely low off-state current, the transistor has an extremely low flow-through current.

Note that instead of the p-channel transistors, n-channel transistors may be applied to the transistors Tr1 and Tr2. In the case where n-channel transistors are used as the transistors Tr1 and Tr2, depletion transistors may be employed as described in Embodiment 3.

Writing, retaining, and reading operation of the memory cell illustrated in FIG. 9 will be described below.

In writing, first, a potential corresponding to data 0 or data 1 is applied to the bit line BL and the bit line BLB.

For example, in the case where data 1 is to be written, the VDD is applied to the bit line BL and the GND is applied to the bit line BLB. Then, a potential (VH) higher than or equal to the sum of the VDD and the threshold voltage of the transistors Tr5 and Tr6 is applied to the word line WL.

Next, the potential of the word line WL is set to be lower than the threshold voltage of the transistors Tr5 and Tr6, whereby the data 1 written to the flip-flop is retained. In the case of the SRAM, a current flowing in retaining data is only the leakage current of the transistors. Here, the transistor shown in Embodiment 1, which has an extremely low off-state current, namely, an extremely low leakage current, is applied to some of the transistors in the SRAM, resulting in a reduction in stand-by power for retaining data.

In reading, the VDD is applied to the bit line BL and the bit line BLB in advance. Then, the VH is applied to the word line WL, so that the bit line BLB is discharged through the transistors Tr5 and Tr3 to be equal to the GND while the potential of the bit line BL is kept at VDD. The potential difference between the bit line BL and the bit line BLB is amplified by a sense amplifier (not illustrated), whereby the retained data 1 can be read.

In the case where data 0 is to be written, the GND is applied to the bit line BL and the VDD is applied to the bit line BLB; then, the VH is applied to the word line WL.

Next, the potential of the word line WL is set to be lower than the threshold voltage of the transistors Tr5 and Tr6, whereby the data 0 written to the flip-flop is retained. In reading, the VDD is applied to the bit line BL and the bit line BLB in advance. Then, the VH is applied to the word line WL, so that the bit line BL is discharged through the transistors Tr6 and Tr4 to be equal to the GND while the potential of the bit line BLB is kept at VDD. The potential difference between the bit line BL and the bit line BLB is amplified by the sense amplifier, whereby the retained data 0 can be read.

According to this embodiment, an SRAM with low stand-by power can be provided.

This embodiment can be implemented in appropriate combination with any of the other embodiments and example.

### Embodiment 5

A central processing unit (CPU) can be configured by using any of the transistor shown in Embodiment 1, the inverter shown in Embodiment 3, and the semiconductor device shown in Embodiment 4.

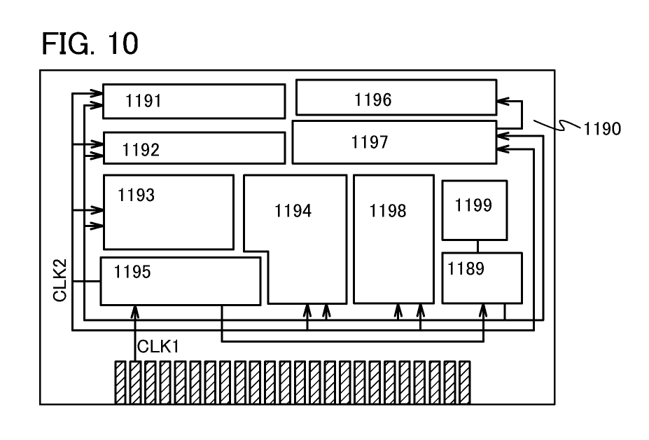

FIG. 10 is a block diagram illustrating a specific configuration of a CPU. The CPU illustrated in FIG. 10 includes an arithmetic logic unit (ALU) 1191, an ALU controller 1192, an instruction decoder 1193, an interrupt controller 1194, a timing controller 1195, a register 1196, a register controller 1197, a bus interface (Bus I/F) 1198, a rewritable ROM 1199, and a ROM interface (ROM I/F) 1189 over a substrate 1190. A semiconductor substrate, an SOI substrate, a glass substrate, or the like is used as the substrate 1190. The ROM 1199 and the ROM interface 1189 may each be provided over a separate chip. Obviously, the CPU illustrated in FIG. 10 is just an example in which the configuration has been simplified, and an actual CPU may have a variety of configurations depending on the application.

An instruction that is input to the CPU through the bus interface 1198 is input to the instruction decoder 1193 and decoded therein, and then, input to the ALU controller 1192, the interrupt controller 1194, the register controller 1197, and the timing controller 1195.

The ALU controller 1192, the interrupt controller 1194, the register controller 1197, and the timing controller 1195 conduct various controls in accordance with the decoded instruction. Specifically, the ALU controller 1192 generates signals for controlling the operation of the ALU 1191. While the CPU is executing a program, the interrupt controller 1194 judges an interrupt request from an external input/output device or a peripheral circuit on the basis of its priority or a mask state, and processes the request. The register controller 1197 generates an address of the register 1196, and reads/writes data from/to the register 1196 in accordance with the state of the CPU.

The timing controller 1195 generates signals for controlling operation timings of the ALU 1191, the ALU controller 1192, the instruction decoder 1193, the interrupt controller 1194, and the register controller 1197. For example, the timing controller 1195 includes an internal clock generator for generating an internal clock signal CLK2 based on a reference clock signal CLK1, and supplies the internal clock signal CLK2 to the above circuits.

In the CPU illustrated in FIG. 10, a memory element is provided in the register 1196. As the memory element in the register 1196, the inverter shown in Embodiment 3 or the semiconductor device shown in Embodiment 4 can be used.

In the CPU illustrated in FIG. 10, the register controller 1197 conducts the operation of retaining data in the register 1196 in accordance with an instruction from the ALU 1191.

Note that by applying the semiconductor device shown in Embodiment 4 to the memory element in the register 1196, the stand-by power of the CPU can be significantly reduced. Specifically, after data under computation or the like is saved in the memory element, it is possible to stop supplying a power supply potential to some of the elements other than the memory element. Even when the supply of a power supply potential to some elements is stopped, the data under computation or the like is retained in the memory element. Hence, the data computation can be restarted when the supply of a power supply potential is restarted. Note that since the memory element needs an extremely low stand-by power, the supply of a power supply potential is substantially stopped in the CPU. Accordingly, the power consumption of the entire CPU can be reduced. For example, the supply of a power supply potential to some elements can be stopped while a user of a personal computer does not input data using an input device such as a keyboard, which results in a reduction in power consumption.

Although the CPU is given as an example, the transistor can also be applied to an LSI such as a digital signal processor (DSP), a custom LSI, or a field programmable gate array (FPGA).

This embodiment can be implemented in appropriate combination with any of the other embodiments and example.

### Embodiment 6

In this embodiment, examples of an electronic device to which any of Embodiments 1 to 5 is applied will be described.

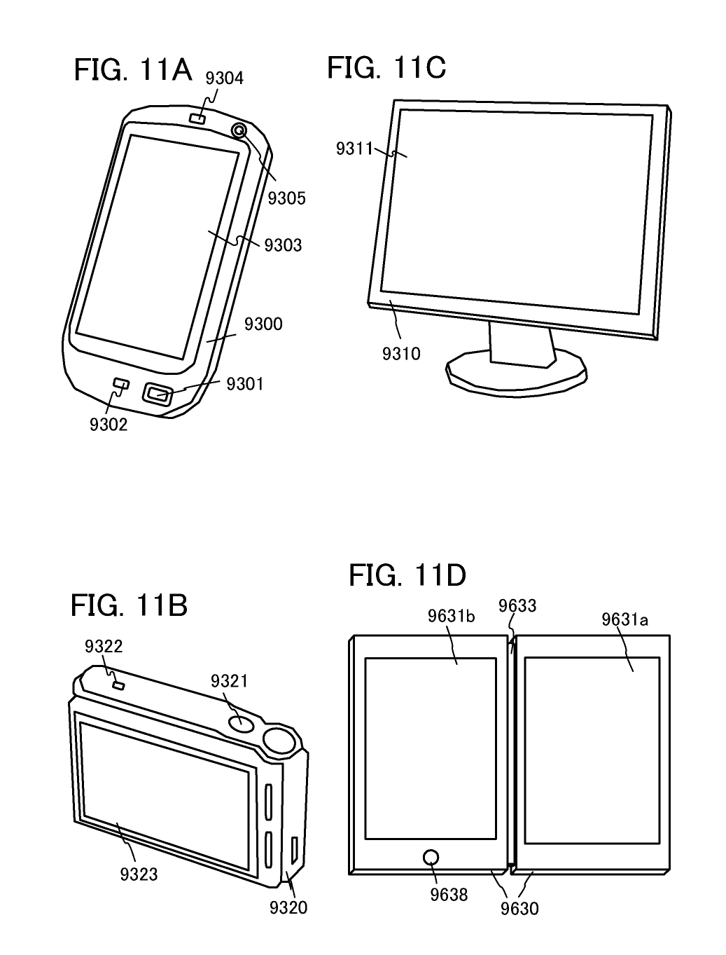

FIG. 11A illustrates a portable information terminal. The portable information terminal illustrated in FIG. 11A includes a housing 9300, a button 9301, a microphone 9302, a display portion 9303, a speaker 9304, and a camera 9305, and has a function as a mobile phone. One embodiment of the present invention can be applied to the display portion 9303. Further, one embodiment of the present invention can be applied to an arithmetic device or a memory circuit in the main body.

FIG. 11B illustrates a digital still camera. The digital still camera illustrated in FIG. 11B includes a housing 9320, a button 9321, a microphone 9322, and a display portion 9323. One embodiment of the present invention can be applied to the display portion 9323. Further, one embodiment of the present invention can be applied to an arithmetic device or a memory circuit in the main body.

FIG. 11C illustrates a display. The display illustrated in FIG. 11C includes a housing 9310 and a display portion 9311. One embodiment of the present invention can be applied to the display portion 9311. Further, one embodiment of the present invention can be applied to an arithmetic device or a memory circuit in the main body.

FIG. 11D illustrates a foldable portable information terminal. The foldable portable information terminal illustrated in FIG. 11D includes a housing 9630, a display portion 9631a, a display portion 9631b, a hinge 9633, and an operation switch 9638. One embodiment of the present invention can be applied to the display portion 9631a and the display portion 9631b. Further, one embodiment of the present invention can be applied to an arithmetic device or a memory circuit in the main body.

Part or whole of the display portion 9631a and/or the display portion 9631b can function as a touch panel. By touching an operation key displayed on the touch panel, a user can input data, for example.

The use of the semiconductor device of one embodiment of the present invention increases the performance of an electronic device and reduces the power consumption of the electronic device.

This embodiment can be implemented in appropriate combination with any of the other embodiments and example.

### Example 1

In this example, the oscillation frequency of a ring oscillator using a transistor of one embodiment of the present invention was measured.

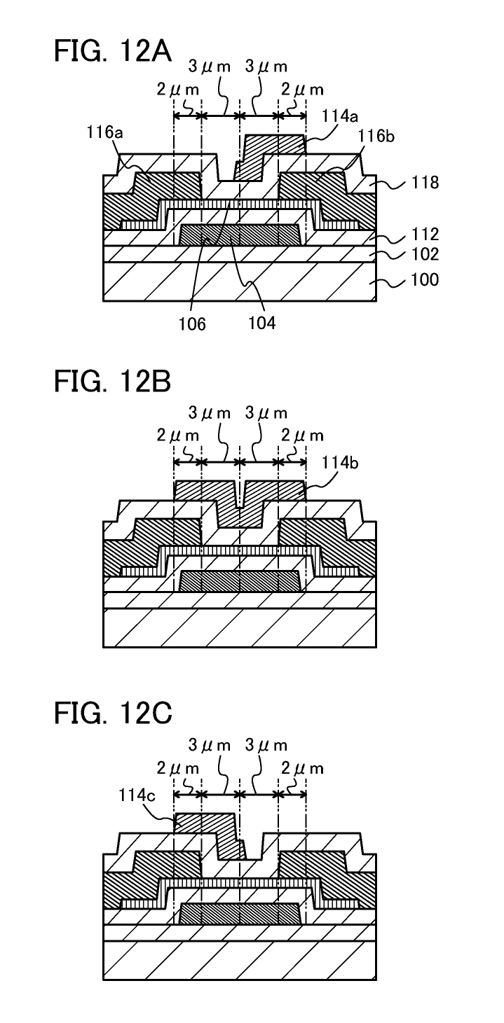

FIGS. 12A to 12C illustrate structures of transistors used in this example. FIG. 12A is a transistor having a structure similar to that of the transistor illustrated in FIGS. 1A to 1C. A gate electrode 114a in FIG. 12A corresponds to the gate electrode 114 in FIGS. 1A to 1C. The transistor illustrated in FIG. 12A is referred to as a transistor TrA. Transistors illustrated in FIGS. 12B and 12C are different from that in FIG. 12A only in the shape of a gate electrode 114b and a gate electrode 114c, respectively, which correspond to the gate electrode 114 illustrated in FIGS. 1A to 1C. The transistors illustrated in FIGS. 12B and 12C are referred to as a transistor TrB and a transistor TrC, respectively.

The transistors TrA, TrB, and TrC each have a channel length of 6 μm and a channel width of 50 μm.

In the transistors TrA, TrB, and TrC, a region where the gate electrode 104 overlaps with the source electrode 116a has a length of 2 μm in the channel length direction, and a region where the gate electrode 104 overlaps with the drain electrode 116b has a length of 2 μm in the channel length direction. Further, in the transistor TrA, a region where the gate electrode 114a overlaps with a channel region has a length of 3 μm in the channel length direction, and a region where the gate electrode 114a overlaps with the drain electrode 116b has a length of 2 μm in the channel length direction. In the transistor TrB, a region where the gate electrode 114b overlaps with the source electrode 116a has a length of 2 μm in the channel length direction, and a region where the gate electrode 114b overlaps with the drain electrode 116b has a length of 2 μm in the channel length direction. In the transistor TrC, a region where the gate electrode 114c overlaps with a channel region has a length of 3 μm in the channel length direction, and a region where the gate electrode 114c overlaps with the source electrode 116a has a length of 2 μm in the channel length direction.

In the transistors TrA, TrB, and TrC, a silicon oxynitride film with a thickness of 200 nm was used for the gate insulating film 112. Further, a silicon oxynitride film with a thickness of 600 nm was used for the gate insulating film 118.

The Vg-Id characteristics of these transistors were evaluated. Table 1 shows the relationship between the back-gate (the gate electrodes 114a, 114b, and 114c) voltage and the threshold voltage Vth of each of the transistors TrA, TrB, and TrC.

TABLE 1

| Back-gate | Threshold voltage [V] | | |
|---|---|---|---|
| voltage [V] | TrA | TrB | TrC |
| −6 | 1.99 | 2.16 | 1.74 |
| −4 | 1.85 | 1.96 | 1.62 |
| −2 | 1.69 | 1.78 | 1.48 |
| 0 | 1.52 | 1.55 | 1.32 |
| 2 | 1.43 | 1.41 | 1.27 |
| 4 | 1.35 | 1.28 | 1.21 |
| 6 | 1.24 | 1.10 | 1.16 |

As shown in Table 1, the threshold voltages of the transistors TrA, TrB, and TrC varied with the back-gate voltage. The ranges of variation of the threshold voltages of the transistors TrA, TrB, and TrC were 0.75 V, 1.06 V, and 0.58 V, respectively, in the range of the back-gate voltage of −6 V to 6 V.

Accordingly, the ranges of variation of the threshold voltages of the transistors had a relationship of TrB>TrA>TrC. It is found that the transistor TrA has a controllable range of threshold voltage wider than that of the transistor TrC with a structure in which the back-gate electrode does not overlap with the drain electrode.

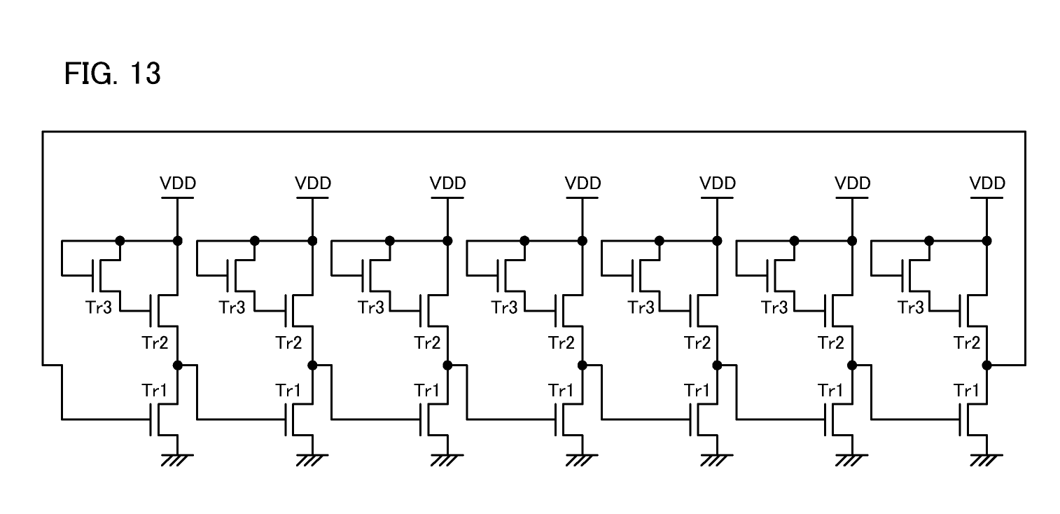

Next, seven-stage ring oscillators were fabricated using plural kinds of transistors having structures similar to those of the transistors TrA, TrB, and TrC. FIG. 13 is a circuit diagram of the ring oscillator. Note that a bootstrap inverter was used in the ring oscillator. For easy understanding, back-gates of the transistors Tr1, Tr2, and Tr3 were not illustrated.

In FIG. 13, the transistor Tr1 has a channel length of 10 μm and a channel width of 100 μm. The transistor Tr2 has a channel length of 10 μm and a channel width of 10 μm. The transistor Tr3 has a channel length of 10 μm and a channel width of 5 μm.

Table 2 shows the comparison results of the oscillation frequencies in the case where the transistors Tr1, Tr2, and Tr3 have a structure similar to that of the transistor TrA, in the case where the transistors Tr1, Tr2, and Tr3 have a structure similar to that of the transistor TrB, and in the case where the transistors Tr1, Tr2, and Tr3 have a structure similar to that of the transistor TrC. Note that in this example, the comparison was performed with the same static characteristics for easy understanding.

TABLE 2

| | Oscillation |
|---|---|
| Transistor | frequency [kHz] |
| TrA | 142.5 |
| TrB | 133.7 |
| TrC | 148.3 |

The calculation showed that the parasitic capacitance decreased with a reduction in the shape of the back-gate, whereby the oscillation frequency increased. The ring oscillator operates by charging the gates of the transistors Tr1. The charging of capacitance includes the charging of the parasitic capacitance between the source electrode and the back-gate electrode of the transistor Tr2 in the preceding stage, and the charging of the parasitic capacitance between the drain electrode and the back-gate electrode of the transistor Tr1 in the preceding stage. In the case where the transistors Tr1, Tr2, and Tr3 have a back-gate structure similar to that of the transistor TrA, the parasitic capacitance between the source electrode and the back-gate electrode of the transistor Tr2 is not generated because the source electrode and the back-gate electrode of the transistor Tr2 do not overlap with each other. On the other hand, in the case where the transistors Tr1, Tr2, and Tr3 have a back-gate structure similar to that of the transistor TrB, the parasitic capacitance between the source electrode and the back-gate electrode of the transistor Tr2 is generated because the source electrode and the back-gate electrode of the transistor Tr2 overlaps with each other. It is thus found that the ring oscillator using the transistors having a back-gate structure similar to that of the transistor TrA has increased frequency characteristics and a higher operation speed as compared to the ring oscillator using the transistor having a back-gate electrode similar to that of the transistor TrB.

This example shows that the transistor with a structure in which the back-gate electrode overlaps with the drain electrode and does not overlap with the source electrode has a high controllability of threshold voltage and the semiconductor device including the transistor has a high operation speed.

This application is based on Japanese Patent Application serial No. 2012-030720 filed with Japan Patent Office on Feb. 15, 2012, the entire contents of which are hereby incorporated by reference.

What is claimed is:

1. A semiconductor device comprising;
a first gate electrode;
a first gate insulating film over the first gate electrode;
an oxide semiconductor film which is over the first gate insulating film and overlaps with the first gate electrode;
a source electrode and a drain electrode in contact with the oxide semiconductor film
a second gate insulating film over the oxide semiconductor film, the source electrode, and the drain electrode; and
a second gate electrode over the second gate insulating film,
wherein the oxide semiconductor film includes a channel region between the source electrode and the drain electrode, and
wherein the second gate electrode overlaps with the channel region and the drain electrode and does not overlap with the source electrode.

2. The semiconductor device according to claim 1,
wherein the first gate electrode overlaps with the channel region, the source electrode, and the drain electrode.

3. The semiconductor device according to claim 1,
wherein the second gate insulating film has an equivalent oxide thickness larger than that of the first gate insulating film.

4. The semiconductor device according to claim 1,
wherein an area where the second gate electrode overlaps with the drain electrode has a width of 1 μm to 3 μm in a channel length direction.

5. The semiconductor device according to claim 1,
wherein the second gate electrode overlaps with the center of the channel region.

6. The semiconductor device according to claim 1,
wherein the source electrode and the drain electrode are provided between the oxide semiconductor film and the first gate insulating film.

7. The semiconductor device according to claim 1,
wherein the source electrode and the drain electrode are provided between the oxide semiconductor film and the second gate insulating film.

8. A semiconductor device comprising;
a first gate electrode;
a first gate insulating film over the first gate electrode;
an oxide semiconductor film which is over the first gate insulating film and overlaps with the first gate electrode;
a source electrode and a drain electrode in contact with the oxide semiconductor film
a second gate insulating film over the oxide semiconductor film, the source electrode, and the drain electrode; and
a second gate electrode over the second gate insulating film,
wherein the oxide semiconductor film includes a channel region between the source electrode and the drain electrode, and
wherein the first gate electrode overlaps with the channel region and the drain electrode and does not overlap with the source electrode.

9. The semiconductor device according to claim 8,
wherein the second gate electrode overlaps with the channel region, the source electrode, and the drain electrode.

10. The semiconductor device according to claim 8,
wherein the first gate insulating film has an equivalent oxide thickness larger than that of the second gate insulating film.

11. The semiconductor device according to claim 8,
wherein an area where the first gate electrode overlaps with the drain electrode has a width of 1 μm to 3 μm in a channel length direction.

12. The semiconductor device according to claim 8,
wherein the first gate electrode overlaps with the center of the channel region.

13. The semiconductor device according to claim 8,
wherein the source electrode and the drain electrode are provided between the oxide semiconductor film and the first gate insulating film.

14. The semiconductor device according to claim 8,
wherein the source electrode and the drain electrode are provided between the oxide semiconductor film and the second gate insulating film.
